(19) United States
(12) Patent Application Publication
(10) Pub. No.: US 2008/0226838 A1
(43) Pub. Date: Sep. 18, 2008

(54) Plasma CVD apparatus and film deposition method

(75) Inventors: Kazuhito Nishimura, Nangoku-shi (JP); Hideki Sasaoka, Kochi-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignees: KOCHI INDUSTRIAL PROMOTION CENTER, Kochi-shi (JP); CASIO COMPUTER CO., LTD., Tokyo (JP)

(21) Appl. No.: 12/004,679

(22) Filed: Dec. 21, 2007

(30) Foreign Application Priority Data
Mar. 12, 2007 (JP) 2007-062065
Mar. 20, 2007 (JP) 2007-073357
Dec. 17, 2007 (JP) 2007-325296

(51) Int. Cl. C23C 16/513; C23C 16/54

(52) U.S. Cl. 427/569; 118/723 R

(57) ABSTRACT

A plasma CVD apparatus includes a first electrode which is disposed in a reacting furnace and on which a substrate is mounted, a second electrode that is disposed above and opposite the first electrode and generates plasma with the first electrode, and a first gas supply nozzle that is disposed at a height between a height of the first electrode in the reacting furnace and a height of the second electrode, and has a plurality of ejection ports formed and arranged in such a way as to surround an area between the first electrode and the second electrode where plasma is generated.

### BACKGROUND OF THE INVENTION

1. Field of the Invention

The present invention relates to a plasma CVD apparatus and a film deposition method.

2. Description of the Related Art

A CVD apparatus which deposits films on a substrate by chemical vapor deposition (CVD) supplies a matrix gas and a reaction gas as a source gas into a reacting furnace and keeps the pressure in the reacting furnace by balancing the gas supply with the exhaust speed. In a plasma CVD apparatus which generates plasma, the gas temperature locally becomes high, causing gas turbulence in the reacting furnace.

It is desirable that a gas containing a reaction gas should flow slowly and uniformly toward the top surface of the substrate where a film which grows by the reaction of the gases is to be the deposited. It is known that the gas flow, if too fast, causes irregular deposition and if the vector of the traveling direction of the reaction gas is not directed toward the substrate, the film growth speed becomes slow.

Conventional plasma CVD apparatuses intended to overcome irregular deposition and keep the growth speed are described in, for example, Japanese Patent No. 2628404, Unexamined Japanese Patent Application KOKAI Publication No. H1-94615 and “DIAMOND SYNTHESIS BY HIGH GRAVITY D.C. PLASMA CVD (HGCVD) WITH ACTIVE CONTROL OF THE SUBSTRATE TEMPERATURE”, by Yoshiyuki Abe et al., Acta Astronautica (Great Britain), 2001, vol. 48, No. 2-3, p. 121-127.

The plasma CVD apparatus described in Japanese Patent No. 2628404 supplies a reaction gas from a direction parallel to or oblique to the top surface of the substrate, supplies a matrix gas from a direction substantially perpendicular to the top surface of the substrate, and presses the reaction gas with the matrix gas to change the direction of the flow of the reaction gas to spray the reaction gas onto the top surface of the substrate.

However, this plasma CVD apparatus is a thermal plasma CVD apparatus which heats a susceptor with a heater to generate thermal plasma, and need not concern the arrangement of electrodes. In case of a DC plasma CVD apparatus where electrodes are disposed at positions facing the substrate, for example, the electrodes become a neck and make it difficult to form the uniform flow of the gas in the direction perpendicular to the substrate.

The plasma CVD apparatus described in Unexamined Japanese Patent Application KOKAI Publication No. H1-94615 ejects a gas directly from a nozzle provided at a cathode facing a substrate. This can allow the reaction gas to flow from the cathode to the substrate.

With this structure, however, at the time plasma is generated, reaction-gas originated active species are present with a high density at the nozzle portion of the cathode which becomes hot. Accordingly, a deposit is gradually stored in the nozzle formed in the cathode, thereby interfering with gas ejection. If the deposit grows from near the nozzle and becomes a projection, an electric field is concentrated on the projection, so that plasma is likely to turn into arc discharge or sparks. Further, a gas whose temperature has dropped by the room temperature or expansion is sprayed toward plasma, so that the positive column may be partially contracted, which may cause irregular film deposition.

The plasma CVD apparatus described in “DIAMOND SYNTHESIS BY HIGH GRAVITY D.C. PLASMA CVD (HGCVD) WITH ACTIVE CONTROL OF THE SUBSTRATE TEMPERATURE” has a gas inlet provided at the upper portion of a reacting furnace and a gas outlet provided at the lower portion thereof to generate the flow of a gas from the cathode toward the anode passing through plasma.

FIGS. 37A and 37B are diagrams for explaining the flow of a gas in the reacting furnace of the plasma CVD apparatus. FIG. 37A shows the configuration of the reacting furnace, and FIG. 37B shows the direction and the flow rate of the gas flow at 1 G by arrows.

In the plasma CVD apparatus, as shown in FIG. 37A, the position of a gas inlet GI and the position of a gas outlet GO are opposite to each other with the center axis of the reacting furnace in between. Therefore, while the gas moving toward the anode is dominant near the lower portion of the cathode, there is a temperature difference between the gas convecting at the gas inlet GI and the gas convecting at the gas outlet GO as shown in FIG. 37B. Further, the local pressure of the gas differs.

In the DC plasma CVD apparatus, the partial pressure state of each component in the active species to be a film deposition material differs depending on the gas temperature in plasma, and as the temperature becomes higher, the value of the partial pressure of active species having a high chemical potential becomes higher than the value of the partial pressure of active species having a relatively low chemical potential. A temperature difference in the reacting furnace causes an irregular temperature in plasma, so that the partial pressure of each active species becomes irregular according to the location, which may result in non-uniform film deposition.

### SUMMARY OF THE INVENTION

As described above, the plasma CVD apparatus described in Japanese Patent No. 2628404 is a thermal plasma CVD apparatus which heats the susceptor with the heater to generate thermal plasma, and, unlike the DC plasma CVD apparatus, is difficult to form the uniform gas flow with respect to the substrate when the electrodes are disposed at positions facing the substrate.

The plasma CVD apparatus described in Unexamined Japanese Patent Application KOKAI Publication No. H1-94615 is not technically satisfactory for it may cause a problem at the time of film deposition and is likely to cause irregular film deposition.

The plasma CVD apparatus described in “DIAMOND SYNTHESIS BY HIGH GRAVITY D.C. PLASMA CVD (HGCVD) WITH ACTIVE CONTROL OF THE SUBSTRATE TEMPERATURE” suffers incomplete uniformity of gas supply to a substrate.

Accordingly, it is an object of the present invention to provide a plasma CVD apparatus and a film deposition method which can uniformly supply a reaction gas to the top surface of a substrate and ensure stable film deposition even when electrodes are disposed at positions facing the substrate.

To achieve the object, according to the first aspect of the invention, there is provided a plasma CVD apparatus comprising:

a first electrode which is disposed in a reacting furnace and on which a substrate is mounted;

a second electrode that is disposed above and opposite the first electrode and generates plasma with the first electrode; and

a first gas supply nozzle that is disposed at a height between a height of the first electrode in the reacting furnace and a height of the second electrode, and has a plurality of ejection ports formed and arranged in such a way as to surround an area between the first electrode and the second electrode where plasma is generated.

A source gas which forms active species with the plasma may be introduced by the first gas supply nozzle.

A source gas and a matrix gas which form active species with the plasma may be introduced by the first gas supply nozzle.

It is preferable that the first gas supply nozzle should laterally eject a gas toward a center axis of the first electrode from the plurality of ejection ports.

It is preferable that the first gas supply nozzle should be disposed in such a way as to surround the first electrode.

It is preferable that the plurality of ejection ports of the first gas supply nozzle should be arranged at equal intervals.

It is preferable that the plurality of ejection ports of the first gas supply nozzle should have equal distances to a center axis of the first electrode.

It is preferable that ejection ports of each ejection port set having two of the plurality of ejection ports of the first gas supply nozzle should be so arranged as to face each other with a center axis of the first electrode being a center.

It is preferable that a height of the plurality of ejection ports of the first gas supply nozzle should be set higher than a topmost point of an area where a positive column of the plasma is generated.

The first gas supply nozzle may have a ring shape, or may be pipes facing each other along a side of the second electrode in the reacting furnace.

The plasma CVD apparatus may further include a second gas supply nozzle that ejects a matrix gas from above the second electrode toward a gas ejected from the first gas supply nozzle.

It is preferable that the plasma CVD apparatus should further comprise a plurality of discharge conduits disposed under the first electrode to discharge a gas from the reacting furnace.

It is particularly preferable that the plurality of discharge conduits should be disposed to surround the first electrode.

The second electrode may comprise a plurality of electrodes, and voltages or currents between the electrodes of the second electrode and the first electrode may be individually set to arbitrary values.

In this case, the plurality of electrodes may include a center electrode facing a center portion of the first electrode and a peripheral electrode facing a peripheral portion of the first electrode, and the value of the voltage or current between the center electrode and the first electrode may be set higher than the value of the voltage or current between the peripheral electrode and the first electrode at a time of rising.

The plurality of electrodes may include a center electrode facing a center portion of the first electrode and a peripheral electrode facing a peripheral portion of the first electrode, and after a positive column is formed between the center electrode and the first electrode, the value of the voltage or current between the center electrode and the first electrode may be set less than the value of the voltage or current between the peripheral electrode and the first electrode.

It is preferable that an insulator should be disposed between the plurality of electrodes.

According to the second aspect of the invention, there is provided a plasma CVD apparatus comprising:

an electrode which has a surface formed of a graphite and on which a substrate to be processed is mounted; and

a plasma generating unit that generates plasma on the electrode to perform a predetermined process on the substrate.

According to the third aspect of the invention, there is provided a film deposition method comprising:

applying a voltage between a first electrode on which a substrate is mounted and a second electrode; and

ejecting a reaction gas from a plurality of ejection ports arranged in such a way as to surround an area where plasma is generated.

### BRIEF DESCRIPTION OF THE DRAWINGS

FIG. 1 is a configuration diagram showing a DC plasma CVD apparatus according to a first embodiment of the present invention;

FIG. 2 is a plan view showing a ring nozzle and discharge ports in FIG. 1;

FIGS. 3A and 3B are diagrams for explaining the configuration of a DC plasma CVD apparatus used in a comparison experiment;

FIG. 4A is a diagram showing the state of glow occurring on a cathode in the DC plasma CVD apparatus shown in FIGS. 3A and 3B;

FIG. 4B is a diagram showing the state of glow occurring on a cathode in the DC plasma CVD apparatus according to the first embodiment;

FIGS. 5A and 5B are diagrams showing the configuration of a DC plasma CVD apparatus according to a second embodiment of the present invention;

FIG. 6 is a configuration diagram showing a DC plasma CVD apparatus according to a third embodiment of the present invention;

FIG. 7 is a diagram showing the outline of a verification experiment;

FIG. 8 is a diagram for explaining the results of the verification experiment;

FIGS. 9A to 9D are images for explaining the results of the verification experiment;

FIGS. 10A to 10C are diagrams showing experiment results;

FIG. 11 is a diagram showing experiment results;

FIGS. 12A and 12B are configuration diagrams showing a DC plasma CVD apparatus according to a fourth embodiment of the present invention;

FIG. 13 is a configuration diagram showing a DC plasma CVD apparatus according to a fifth embodiment of the present invention;

FIG. 14 is a diagram showing a cathode, a source gas nozzle and exhaust conduits of the DC plasma CVD apparatus in FIG. 13 from above;

FIG. 15 is a cross-sectional view showing the DC plasma CVD apparatus in FIG. 13 from sideward;

FIGS. 16A and 16B are configuration diagrams showing a DC plasma CVD apparatus according to a sixth embodiment of the present invention;

FIG. 17 is a diagram showing a cathode, a source gas nozzle and exhaust conduits of the DC plasma CVD apparatus in FIG. 16A from above;

FIG. 18 is a cross-sectional view showing the DC plasma CVD apparatus in FIG. 16A from sideward;

FIG. 19 is a configuration diagram showing a DC plasma CVD apparatus according to a seventh embodiment of the present invention;

FIG. 20 is a diagram showing a cathode, a reaction gas nozzle, a matrix gas nozzle and exhaust conduits of the DC plasma CVD apparatus in FIG. 19 from above;

FIG. 21 is a cross-sectional view showing the DC plasma CVD apparatus in FIG. 19 from sideward;

FIGS. 22A and 22B are configuration diagrams showing a DC plasma CVD apparatus according to an eighth embodiment of the present invention;

FIG. 23 is a diagram showing a cathode, a reaction gas nozzle, a matrix gas nozzle and exhaust conduits of the DC plasma CVD apparatus in FIG. 22A from above;

FIG. 24 is a cross-sectional view showing the DC plasma CVD apparatus in FIG. 22A from sideward;

FIG. 25 is a diagram showing a modification of the cathode;

FIG. 26 is a diagram showing a modification of the cathode;

FIG. 27 is a diagram showing a modification of the cathode;

FIG. 28 is a diagram showing a modification of the cathode;

FIGS. 29A and 29B are diagrams showing a modification of a cooling member;

FIGS. 30A and 30B are diagrams showing a modification of the cooling member;

FIG. 31 is a configuration diagram showing a plasma CVD apparatus according to a ninth embodiment of the present invention;

FIG. 32 is a diagram for explaining the difference between temperatures of a graphite electrode and a molybdenum electrode at the time of film deposition;

FIG. 33 is a graph showing a change in power applied to plasma;

FIGS. 34A and 34B are diagrams showing the states of an anode after film deposition;

FIG. 35 is a configuration diagram showing the outline of a modification of the plasma CVD apparatus;

FIG. 36 is a configuration diagram showing the outline of a modification of the plasma CVD apparatus;

FIG. 37A is a diagram showing the configuration of a conventional plasma CVD apparatus; and

FIG. 37B is a diagram for explaining the flow of a gas in a reacting furnace in the conventional plasma CVD apparatus shown in FIG. 37A.

### DETAILED DESCRIPTION OF THE PREFERRED EMBODIMENTS

Preferred embodiments of the present invention will be described below with reference to the accompanying drawings.

### First Embodiment

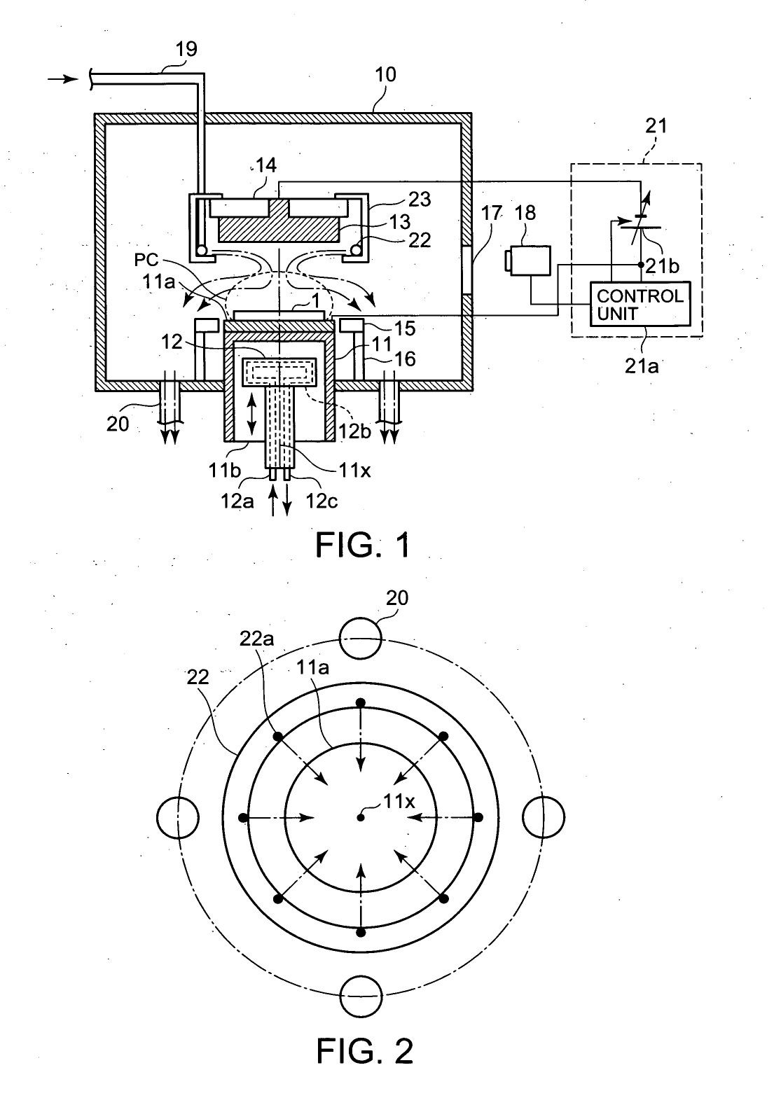

FIG. 1 is a configuration diagram showing a DC plasma CVD apparatus according to a first embodiment of the present invention.

The DC plasma CVD apparatus forms a film on the top surface of a substrate 1 to be processed, and has a chamber 10 as a reacting furnace. The chamber 10 shields the substrate 1 from the outside air.

A columnar steel stage 11 is disposed in the chamber 10. A disc-shaped anode 11a of a material having a high thermal conductivity and a high melting point, such as molybdenum or graphite, is mounted on the stage 11. The anode 11a has a diameter of, for example, 80 mm and a thickness of 20 mm. The substrate 1 which is rectangular is fixed on an upper mount surface of the anode 11a. The stage 11 is set so that the stage 11 rotates about an axis 11x together with the anode 11a.

The stage 11 underlying the anode 11a is provided with closed space 11b where a cooling member 12 is disposed. The cooling member 12 is provided to cool down the substrate 1 as needed, and is configured to be movable up and down as indicated by arrows by a moving mechanism (not shown). The cooling member 12 is formed of a metal having a high thermal conductivity, such as copper. A coolant, such as cooled water or a cooled solution of calcium chloride, enters a flow passage 12b in the cooling member 12 from a conduit 12a and is discharged from a conduit 12c to circulate in the cooling member 12 to cool the whole cooling member 12.

As the cooling member 12 moves upward, the top side of the cooling member 12 buts on the bottom side of the stage 11 which cools the overlying anode 11a that in turn takes heat away from the substrate 1. The coolant discharged from the conduit 12c is cooled by a cooling unit (not shown), and is fed out again to the conduit 12a to thereby circulate. The top side of the cooling member 12 should preferably be larger than the substrate 1 to uniformly cool the substrate 1 in the planar direction.

The space 11b provided under the anode 11a is partitioned by the stage 11, so that the interior of the space 11b is filled with a gas or is open to the air.

A disc-shaped cathode 13 is disposed above the anode 11a. The cathode 13 is supported on a cathode support 14 and faces the anode 11a. The cathode 13 is formed of molybdenum, graphite or the like having a high melting point, and has a diameter of, for example, 80 mm and a thickness of 20 mm. The cathode support 14 is made of a heat-resistant oxide, such as quartz glass or alumina, a heat-resistant nitride, such as aluminum nitride or silicon nitride, or a heat-resistant carbide, such as silicon carbide. The distance between the cathode 13 and the anode 11a is 50 mm, for example.

A passage where the coolant flows may be formed in the cathode 13. The flow of the coolant can suppress overheating of the cathode 13. Preferable coolants are water, calcium chloride solution and the like which are supplied from outside the chamber 10.

An insulating unit 15 for suppressing occurrence of arcs is disposed near the outer surface of the anode 11a. The insulating unit 15 comprises at least one of a heat-resistant oxide, such as quartz glass or alumina, a heat-resistant nitride, such as aluminum nitride or silicon nitride, and a heat-resistant carbide, such as silicon carbide.

The insulating unit 15, shaped like a ring, is supported at the same height as the anode 11a by a support 16 provided upright at the bottom portion of the chamber 10 and its inner side surrounds the anode 11a. The outside diameter of the insulating unit 15 is set equal to or greater than 1.2 times the maximum outside diameter of the cathode 13.

Because the insulating unit 15 serves to suppress occurrence of abnormal discharge (arc discharge, sparking) between the cathode 13 and the anode 11a, the insulating unit 15 is disposed along the outer surface of the anode 11a and opposite the cathode 13. The insulating unit 15 may be arranged to hide the side faces of the anode 11a.

A window 17 is formed in the side face of the chamber 10 to permit observation of the interior of the chamber 10. A heat-resistant glass is fitted in the window 17 to secure the airtightness inside the chamber 10. A radiation thermometer 18, which measures the temperature of the substrate 1 via, for example, the window 17, is disposed outside the chamber 10.

The DC plasma CVD apparatus has a source system (not shown) which supplies a source gas containing a reaction gas through a gas tube 19, an exhaust system (not shown) which discharges a gas from inside the chamber 10 through exhaust conduits 20, and a voltage setting unit 21.

The gas tube 19 is inserted into the chamber 10 through a hole provided in the chamber 10, and at least a part of the gas tube 19 in the reacting furnace is formed by an insulator, such as fluororesin or silicon gum. A sealant seals between the hole of the chamber 10 and the outer surface of the gas tube 19 to secure the airtightness inside the chamber 10. In the chamber 10, the gas tube 19 is connected to a ring nozzle 22 which is a gas supply nozzle. While the ring nozzle 22 preferably has a complete circular shape, it may have the shape of a regular polygon.

FIG. 2 is an explanatory diagram of the ring nozzle 22 and the exhaust conduits 20.

The ring nozzle 22 generally has a ring shape and is hollow so that the source gas flows therein. A plurality of ejection ports 22a with equal apertures are arranged in the ring-like inner surface of the ring nozzle 22. The ejection ports 22a are provided at equal distances to the axis 11x or the center axis of the anode 11a and the individual ejection ports 22a are provided at opposite positions in point symmetrical with respect to the axis 11x as the center. As will be described later, the ejection ports 22a are formed in such a way as to surround an area where plasma is generated, and the source gas is uniformly ejected toward the axis 11x from the ejection ports 22a.

The ring nozzle 22 is supported by an insulating nozzle support 23 attached to the cathode support 14. The ejection ports 22a of the ring nozzle 22 are set higher than the height of the anode 11a at a position below the lowermost portion of the cathode support 14 (topmost portion of a side face of the cathode 13 which is exposed through the cathode support 14) and at a position higher than the highest point of a positive column PC formed between the anode 11a and the cathode 13. As the ring nozzle 22 is supported in this range, the source gas easily enters between the cathode 13 and the anode 11a, and can prevent the gas temperature in the positive column PC from being locally cooled by ejection of the source gas.

The inside diameter of the ring nozzle 22 is larger than the outside diameter of the cathode 13 and the outside diameter of the anode 11a. The center of the ring nozzle 22 lies on the axis 11x of the anode 11a. Angles toward individual ejection ports 22a from the center of the anode 11a are approximately even.

Four exhaust conduits 20 respectively penetrate four holes formed in the bottom side of the chamber 10 at equal intervals to surround the stage 11 or the anode 11a abut the axis 11x. A sealant seals between each hole and the outer surface of the associated exhaust conduit 20.

The voltage setting unit 21 is a control device that sets the value of a voltage or current between the anode 11a and the cathode 13 and has a variable power source 21b. The voltage setting unit 21 is connected to the anode 11a and the cathode 13 by leak lines. The lead lines pass through holes provided in the chamber 10 to be connected to the cathode 13 and the anode 11a. The holes in the chamber 10 where the lead lines pass are sealed by a sealant.

The voltage setting unit 21 has a control unit 21a which is connected to the radiation thermometer 18 by a lead line and to the variable power source 21b by a lead line. When activated, the control unit 21a refers to the temperature of the substrate 1 measured by the radiation thermometer 18, and adjusts the value of the voltage or current between the anode 11a and the cathode 13 so that the temperature of the substrate 1 becomes a predetermined value.

Next, a description will be given of a deposition process which forms a film on the substrate 1 using the DC plasma CVD apparatus in FIG. 1.

In the deposition process, an electron discharge film comprising a carbon nanowall is deposited on the top surface of the substrate 1.

The carbon nanowall is structured as a plurality of petaloid (fan-shaped) thin carbon pieces having curved surfaces stand upright and linked together in random directions. Each thin carbon piece is formed by several to several tens of graphene sheets each having a lattice pitch of 0.34 nm.

In the deposition process, first, a nickel plate, for example, is cut out as the substrate 1 and is substantially subjected to degreasing/ultrasonic cleaning with ethanol or acetone. Next, if the top surface of the substrate 1 is formed of a metal, the top surface of the substrate 1 is covered very thinly with multiple insulating particles having a high melting point and a small diameter, such as diamond particles or aluminum oxide particles. This is because when the top surface of the substrate 1 is formed of a metal, active species generated by a part of the source gas are diffused in the substrate 1 so that an active-species oriented deposit is difficult to be deposited on the top surface of the substrate 1. However, thin coverage of the top surface of the substrate 1 with multiple insulating particles can allow a deposit to be deposited from the top surface of the substrate 1 while hardly shielding the electric field between the anode 11a and the cathode 13.

This substrate 1 is placed on the anode 11a.

When mounting the substrate 1 is completed, next, the chamber 10 is depressurized by using the exhaust system, and a hydrogen gas and a reaction gas and a reaction gas (carbon contained compound) of a compound containing a carbon in a composition, such as methane, are supplied into the chamber 10 from the gas tube 19. The source gas is ejected from the ejection ports 22a of the ring nozzle 22.

It is desirable that a reaction gas of a compound containing a carbon in a composition should lie in a range of 3 volt % to 30 vol % of the whole compositions. For example, the flow rate of methane is set to 50 sccm, the flow rate of hydrogen is set to 500 sccm, and the entire pressure is set to 0.05 to 1.5 atm, preferably 0.07 to 0.1 atm. The anode 11a is rotated with the substrate 1 about the axis 11x at 1 rpm to set a temperature variation on the substrate 1 within 5%, and a DC voltage is applied between the anode 11a and the cathode 13 to generate plasma and control the plasma state and the temperature of the substrate 1.

At the time of depositing a carbon nanowall, film deposition is performed at a temperature of 900° C. to 1100° C. set as the temperature of that portion of the substrate 1 where the carbon nanowall is formed. This temperature is measured by the radiation thermometer 18. At this time, the cooling member 12 is separated substantially from the anode 11a to avoid influence on the temperature of the anode 11a. The radiation thermometer 18 is so set as to decrease the plasma radiation of the DC plasma CVD apparatus and acquire the temperature only from the heat radiation at the top surface of the substrate 1.

When a diamond layer containing multiple diamond particles is laminated on the carbon nanowall while changing the film property of the electron discharge film during the carbon nanowall deposition process, for example, the cooling member 12 is moved upward to abut on the anode 11a. Accordingly, the temperature of the substrate 1 can be significantly lowered to enable lamination of the diamond layer. As the diamond layer grows, sp² bonded carbon of a rod shape, which is a modified part of the carbon nanowall, and, unlike a carbon nanotube, having a filled core, grows. This rod-shaped carbon extends to protrude from the top surface of the diamond layer, and is a portion on which structurely an electric field is likely to be concentrated and which discharges electrons.

At the end stage of film deposition, application of the voltage between the anode 11a and the cathode 13 is stopped, then the supply of the source gas is stopped and a nitrogen gas is supplied into the chamber 10 as a purge gas to provide a nitrogen atmosphere in the chamber 10, after which the substrate 1 is removed with the temperature returned to normal temperature.

The DC plasma CVD apparatus according to the embodiment has the following advantages (1) to (6).

(1) The ring nozzle 22 is disposed in the chamber 10, the source gas is ejected toward the axis 11x laterally or in the lateral inward direction, from the ejection ports 22a, and is exhausted from the four exhaust conduits 20. As the ejection ports 22a are arranged in the ring nozzle 22 at equal intervals and the exhaust conduits 20 are disposed around the stage 11 at equal intervals, the flow of the source gas becomes uniform symmetrically with respect to the axis 11x in the chamber 10. Because the cathode 13 and the cathode support 14 do not interfere with the flow of the source gas, the source gas efficiently flows to directly under the center of the cathode 13 where the axis 11x is located, so that the source gas is uniformly distributed from an end to the center on the substrate 1, and the density of the active species produced from a part of the source gas in the positive column PC becomes uniform. This can ensure uniform film deposition on the top surface of the substrate 1.

A description will now be given of the result of checking the influence originated from the difference in the flow of the source gas in an experiment.

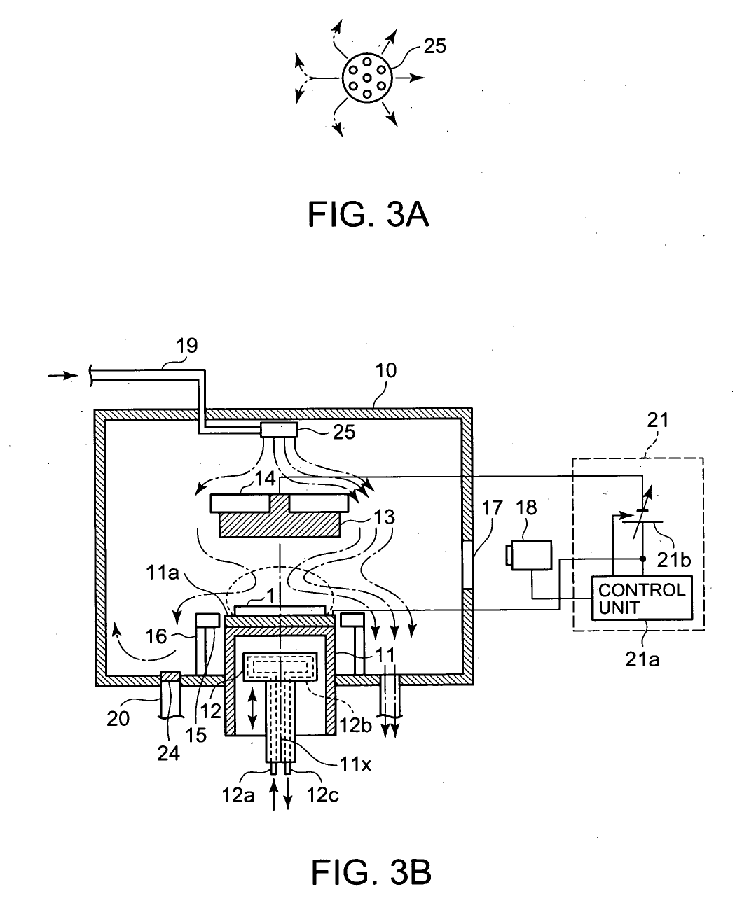

FIGS. 3A and 3B are diagrams for explaining the configuration of a DC plasma CVD apparatus used in a comparison experiment.

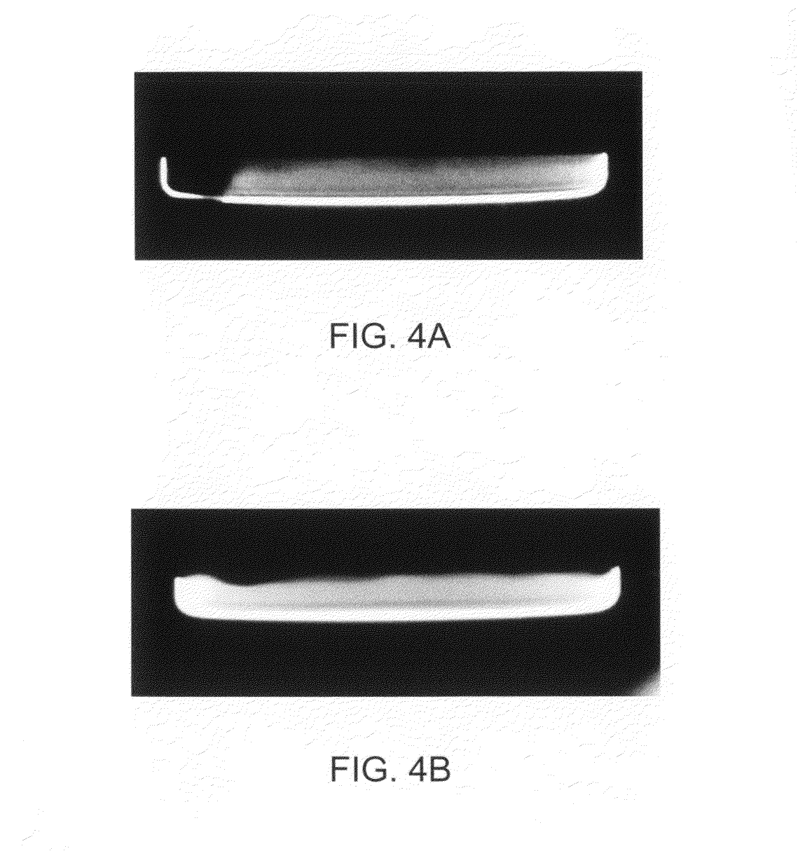

FIG. 4A is a diagram showing the state of glow occurring on a cathode in the DC plasma CVD apparatus shown in FIGS. 3A and 3B. FIG. 4B is a diagram showing the state of glow occurring on the cathode in the DC plasma CVD apparatus according to the first embodiment.

In the experiment, a part of the DC plasma CVD apparatus in FIG. 1 is changed in such a way that the flow of the source gas does not become symmetrical with respect to the axis 11x and the cathode 13 is disposed between the anode 11a and the nozzle to become a steric interference. As shown in FIG. 3B, for example, the ring nozzle 22 and the nozzle support 23 are removed from inside the chamber 10, the gas tube 19 is connected to a gas shower nozzle 25 located above the cathode support 14 in the chamber 10, so that the gas is ejected downward like a shower from the gas shower nozzle 25, and only one of a plurality of exhaust conduits 20 is left while stoppers 24 are fitted in the other exhaust conduits 20 to disable exhaust from the exhaust conduits 20 having the stoppers 24 fitted therein. The other configuration is the same as that of the DC plasma CVD apparatus in FIG. 1. To show effects originating from the positions of the inlet and outlet for the source gas with respect to the movement of the source gas as a fluid, the DC plasma CVD apparatus in the comparison experiment, like the DC plasma CVD apparatus of the embodiment, is provided with the insulating unit 15.

The states of glowing occurring under the cathode 13 in the DC plasma CVD apparatus modified as shown in FIG. 3B and the DC plasma CVD apparatus in FIG. 1 were observed. Note that the source gas is a hydrogen gas with a flow rate of 500 sccm, a gas pressure is 30 torr, and a current of 2 A flows across the cathode 13.

In the DC plasma CVD apparatus modified as shown in FIG. 3B, the source gas ejected from the gas shower nozzle 25 is led toward one exhaust conduit 20 without the stopper 24, so that the source gas does not flow radially unlike the one indicated by arrows in FIG. 3A, and the gas does not flow symmetrically with respect to the axis 11x at the downstream of the cathode 13 and the flow of the source gas is concentrated toward the exhaust conduit 20 without the stopper 24 as indicated by two-dot chain lines in FIG. 3B. As the cathode 13 becomes a steric interference with the flow of the source gas, the source gas becomes difficult to go around the cathode 13 to reach the axis 11x at the center of the anode 11a, thus causing an intra-plane variation in the density of the reached active species at the top surface of the substrate 1. Such a variation becomes more prominent as the substrate 1 becomes larger, which makes the cathode 13 and the anode 11a larger.

In the DC plasma CVD apparatus modified as shown in FIG. 3B, as shown in FIG. 4A. The tilting of the shape of the cathode glow at the cathode 13 indicates that the temperature distribution also has an inclination, so that film deposition on the substrate 1 is likely to vary. In the DC plasma CVD apparatus modified as shown in FIG. 1, by way of contrast, the glow occurring at the cathode 13 is not tilted. This can therefore ensure uniform film deposition on the substrate 1.

(2) Because the gas tube 19 is formed by an insulator, and the ring nozzle 22 is supported on the insulator nozzle support 23 to insulate the ring nozzle 22 from the power source or the ground, wasteful arc discharge or the like from the cathode 13 or the anode 11a does not occur.

(3) Because the inside diameter of the ring-shaped ring nozzle 22 is greater than the outside diameters of the cathode 13 and the anode 11a, the ring nozzle 22 does not overlap the positive column PC having a high density of the active species between the cathode 13 and the anode 11a, so that there is not much a plasma-oriented temperature rise at the portion of the ejection ports 22a, thereby suppressing occurrence of deposits at the ejection ports 22a.

(4) Because the height of the ejection ports 22a of the ring nozzle 22 is higher than the maximum point of the positive column PC, the gas temperature at the positive column PC is not locally cooled from sideward by a low-temperature gas ejected from the ejection ports 22a, so that the symmetry of the shape of the positive column PC is not disturbed.

(5) The insulating unit 15 prevents occurrence of arc discharge which interferes with the uniform film deposition toward the outer surface of the anode 11a from the cathode 13.

(6) The ring nozzle 22 is disposed at the same position as the electrode surface of the cathode 13 or a position lower than the electrode surface and the source gas discharged laterally from the ring nozzle 22 is led toward the underlying exhaust conduits 20. This can prevent highly reactive active species produced in the positive column PC from being diffused to contact the cathode 13. It is therefore possible to prevent deposition of the active species on the cathode 13 which causes arc discharge or sparks.

### Second Embodiment

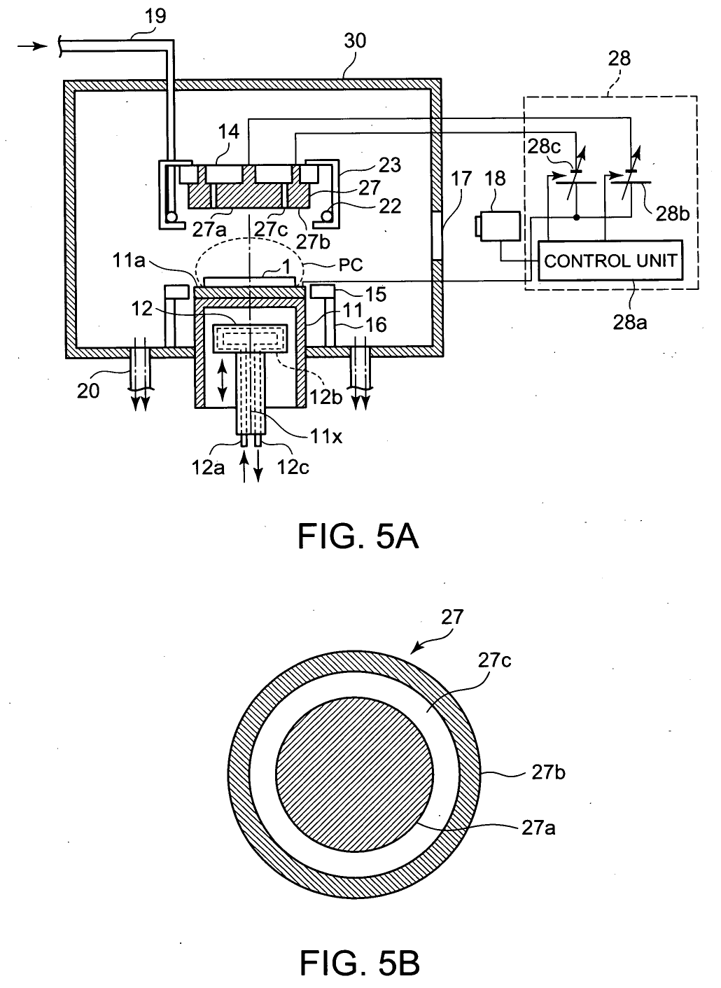

FIGS. 5A and 5B are configuration diagrams of a DC plasma CVD apparatus according to a second embodiment of the present invention. Common reference numerals are given to those components in FIGS. 5A and 5B which are common to the components in FIG. 1.

This DC plasma CVD apparatus is the DC plasma CVD apparatus in FIG. 1 whose cathode 13 is changed to a cathode 27 and whose voltage setting unit 21 is changed to a voltage setting unit 28.

The cathode 27 has a disc-shaped center electrode 27a facing the center portion of the anode 11a, a peripheral electrode 27b which is shaped like a ring (see FIG. 5B) surrounding the center electrode 27a, is concentric to the center electrode 27a and faces the peripheral portion of the anode 11a, and an insulating part 27c of ceramics or the like fully filled between the center electrode 27a and the peripheral electrode 27b.

Without the insulating part 27c intervening between the center electrode 27a and the peripheral electrode 27b, the electric field intensity on the side wall of the center electrode 27a and the side wall of the peripheral electrode 27b facing each other as well as on the substrate 1 becomes weak, producing a portion uncovered with the cathode glow, unless the distance between the center electrode 27a and the peripheral electrode 27b is provided sufficiently long. Because this portion has less ion bombardment, a deposit is likely to be deposited there. Such a deposit causes arc discharge or sparking. In this respect, the insulating part 27c is intervened to prevent a film from being deposited on the side wall of the center electrode 27a and the side wall of the peripheral electrode 27b facing each other.

The voltage setting unit 28 has a control unit 28a, and variable power sources 28b, 28c.

The control unit 28a is connected to the radiation thermometer 18 by a lead line. The control unit 28a has a capability of controlling the variable power sources 28b, 28c and individually setting the voltage or current between the anode 11a and the center electrode 27a and the voltage or current between the anode 11a and the center electrode 27b. The other configuration is the same as that of the DC plasma CVD apparatus in FIG. 1.

In case where a film is formed on the substrate 1 using the DC plasma CVD apparatus in FIGS. 5A and 5B, the substrate 1 is rotated at 1 rpm at the rising of plasma, the potential difference between the stage 11 and the center electrode 27a is made greater than the potential difference between the stage 11 and the peripheral electrode 27b under the control of the voltage setting unit 28 to set the voltage between the cathode 27 and the anode 11a. Such voltage application produces a small positive column PC between the anode 11a and the center electrode 27a. This can prevent occurrence of arc discharge which would frequently occur at the time of producing a large positive column from the beginning.

After the stable positive column PC is formed at the upper portion of the center portion of the substrate 1 by such application of the voltage or current, the control unit 28a applies the voltage or current in such a way that the value of the voltage or current between the anode 11a and the center electrode 27a becomes less than the value of the voltage or current between the anode 11a and the peripheral electrode 27b to approximate the temperature between the anode 11a and the center electrode 27a to the temperature between the anode 11a and the peripheral electrode 27b or make those temperatures approximately identical before performing film deposition on the substrate 1.

In the embodiment, as described above, the cathode 27 comprises the center electrode 27a and the peripheral electrode 27b, and the value of the voltage or current between the anode 11a and the center electrode 27a and value of the voltage or current between the anode 11a and the peripheral electrode 27b can be independently set. At the rising of plasma, the voltage between the anode 11a and the center electrode 27a is set higher than the voltage between the anode 11a and the peripheral electrode 27b. Accordingly, the positive column PC can be formed with the distance between the anode 11a and the cathode 27 made shorter. The voltage to be applied to the anode 11a and the cathode 27 cab be low, thereby suppressing the frequent occurrence of arc discharge or sparking.

Further, the current flowing across the peripheral electrode 27b is made smaller than the current flowing across the center electrode 27a to produce a positive column PC concentrated on the center of the substrate 1, after which the power to be applied to the peripheral electrode 27b is increased to increase the current flowing across the peripheral electrode 27b. This makes it possible to prevent local arc discharge which occurs at the initial stage of film deposition after which the positive column PC can be grown to the necessary size.

### Third Embodiment

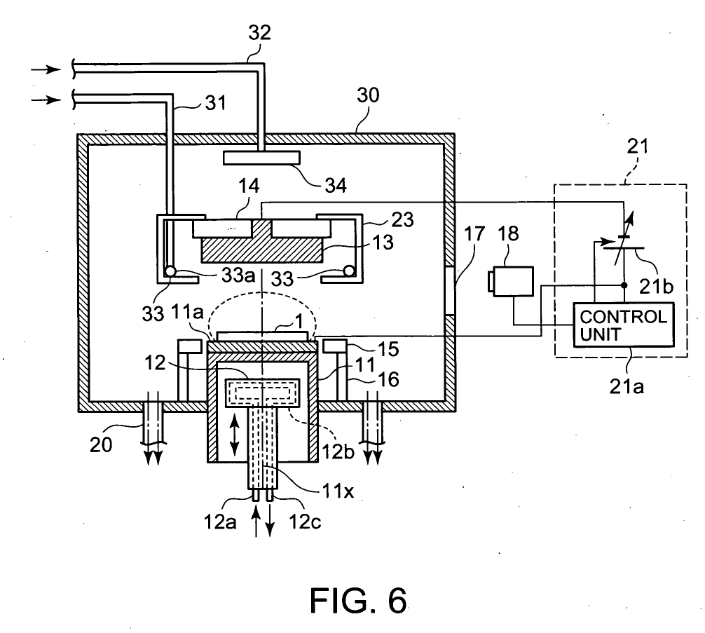

FIG. 6 shows a configurational example of a DC plasma CVD apparatus according to a third embodiment of the present invention. Common reference numerals are given to those components in FIG. 6 which are common to the components in FIG. 1.

The DC plasma CVD apparatus has a chamber 30 as a reacting furnace. The chamber 30 shields the substrate 1 from the outside air.

A columnar steel stage 11 is disposed in the chamber 30. A disc-shaped anode 11a of a material having a high thermal conductivity and a high melting point, such as molybdenum or graphite, is mounted on the stage 11. The substrate 1 which is rectangular is fixed on an upper mount surface of the anode 11a. The stage 11 is set so that the stage 11 rotates about an axis 11x together with the anode 11a.

The stage 11 underlying the anode 11a is provided with closed space 11b where a cooling member 12 is disposed. The cooling member 12 is provided to cool down the substrate 1 as needed, and is configured to be movable up and down as indicated by arrows by a moving mechanism (not shown). The cooling member 12 is formed of a metal having a high thermal conductivity, such as copper. A coolant, such as cooled water or a cooled solution of calcium chloride, enters a flow passage 12b in the cooling member 12 from a conduit 12a and is discharged from a conduit 12c to circulate in the cooling member 12 to cool the whole cooling member 12.

As the cooling member 12 moves upward, the top side of the cooling member 12 buts on the bottom side of the stage 11 which cools the overlying anode 11a that in turn takes heat away from the substrate 1. The coolant discharged from the conduit 12c is cooled by a cooling unit (not shown), and is fed out again to the conduit 12a to thereby circulate.

A disc-shaped cathode 13 is disposed above the anode 11a. The cathode 13 is supported on a cathode support 14 and faces the anode 11a. The cathode 13 is formed of molybdenum, graphite or the like having a high melting point. The cathode support 14 is made of a heat-resistant oxide, such as quartz glass or alumina, a heat-resistant nitride, such as aluminum nitride or silicon nitride, or a heat-resistant carbide, such as silicon carbide.

A passage where the coolant flows may be formed in the cathode 13. The flow of the coolant can suppress overheating of the cathode 13.

An insulating unit 15 for suppressing occurrence of arcs is disposed near the outer surface of the anode 11a. The insulating unit 15 comprises at least one of a heat-resistant oxide, such as quartz glass or alumina, a heat-resistant nitride, such as aluminum nitride or silicon nitride, and a heat-resistant carbide, such as silicon carbide.

The insulating unit 15, shaped like a ring, is supported at the same height as the anode 11a by a support 16 provided upright at the bottom portion of the chamber 30 and its inner side surrounds the anode 11a. The outside diameter of the insulating unit 15 is set equal to or greater than 1.2 times the maximum outside diameter of the cathode 13.

Because the insulating unit 15 serves to suppress occurrence of abnormal discharge (arc discharge, sparking) between the cathode 13 and the anode 11a, the insulating unit 15 may be disposed along the outer surface of the anode 11a and opposite the cathode 13 hide the side faces of the anode 11a.

A window 17 is formed in the side face of the chamber 30 to permit observation of the interior of the chamber 30. A heat-resistant glass is fitted in the window 17 to secure the airtightness inside the chamber 30. A radiation thermometer 18, which measures the temperature of the substrate 1 via, for example, the window 17, is disposed outside the chamber 30.

The DC plasma CVD apparatus has a source system (not shown) which supplies a reaction gas to be the source for active species through a gas tube 31, a source system (not shown) which supplies a matrix gas (carrier gas) through a gas tube 32, an exhaust system (not shown) which discharges a gas from inside the chamber 30 through exhaust conduits 20, and a voltage setting unit 21.

The gas tube 31, which is made by an insulator, passes through a hole provided in the chamber 30. A sealant seals between the hole and the outer surface of the gas tube 31 to secure the airtightness inside the chamber 30. In the chamber 30, the gas tube 31 is connected to a ring nozzle 33.

The ring nozzle 33 is similar to the ring nozzle 22 shown in FIG. 2. A plurality of ejection ports 33a with equal apertures are arranged in the ring-like inner surface of the ring nozzle 33, and are provided at equal distances to the axis 11x or the center axis of the anode 11a. The individual ejection ports 33a are provided at opposite positions in point symmetrical with respect to the axis 11x as the center to uniformly eject the source gas toward the axis 11x from the ejection ports 33a.

The ring nozzle 33 is supported by an insulating nozzle support 23 attached to the cathode support 14. The ejection ports 33a of the ring nozzle 33 are set at a position below the lowermost portion of the cathode support 14 (topmost portion of a side face of the cathode 13 which is exposed through the cathode support 14) and at a position higher than the highest point of a positive column PC formed between the anode 11a and the cathode 13. As the ring nozzle 33 is supported in this range, the reaction gas easily enters between the cathode 13 and the anode 11a, and can prevent the disturbance of the symmetry of the positive column PC which is caused by locally cooling by ejection of the reaction gas.

The inside diameter of the ring nozzle 33 is larger than the outside diameter of the cathode 13 and the outside diameter of the anode 11a. The center of the ring nozzle 33 lies on the axis 11x of the anode 11a. Angles toward individual ejection ports 33a from the center of the anode 11a are approximately even.

Four exhaust conduits 20 respectively penetrate four holes formed in the bottom side of the chamber 30 at equal intervals to surround the stage 11 abut the axis 11x. A sealant seals between each hole and the outer surface of the associated exhaust conduit 20.

The voltage setting unit 21 is a control device that sets the value of a voltage or current between the anode 11a and the cathode 13 and has a variable power source 21b. The voltage setting unit 21 is connected to the anode 11a and the cathode 13 by lead lines. The lead lines pass through holes provided in the chamber 30 to be connected to the cathode 13 and the anode 11a. The holes in the chamber 30 where the lead lines pass are sealed by a sealant.

The voltage setting unit 21 has a control unit 21a which is connected to the radiation thermometer 18 by a lead line and to the variable power source 21b by a lead line. When activated, the control unit 21a refers to the temperature of the substrate 1 measured by the radiation thermometer 18, and adjusts the value of the voltage or current between the anode 11a and the cathode 13 so that the temperature of the substrate 1 becomes a predetermined value.

The gas tube 32, which is made by an insulator, passes through a hole provided in the chamber 30. A sealant seals between the hole and the outer surface of the gas tube 32 to secure the airtightness inside the chamber 30. In the chamber 30, the gas tube 32 is connected to a gas shower nozzle 34.

The gas shower nozzle 34 is disposed above the cathode support 14 supporting the cathode 13 and above the ring nozzle 33. A plurality of ejection ports with equal apertures are formed in the bottom side of the gas shower nozzle 34 concentrically or radially about the axis 11x. The individual ejection ports are provided at opposite positions in point symmetrical with respect to the axis 11x as the center to eject the matrix gas downward like a shower.

The basic operation in performing film deposition using the DC plasma CVD apparatus of the embodiment is similar to that of the case of using the DC plasma CVD apparatus of the first embodiment. It is to be noted that in the DC plasma CVD apparatus of the embodiment, the matrix gas and the reaction gas are introduced independently and the reaction gas is ejected from the ring nozzle 33 in the lateral inward direction while the matrix gas is ejected downward from the gas shower nozzle 34. The matrix gas changes the vector of the flow of the reaction gas ejected laterally so that the reaction gas flows toward the obliquely underlying substrate 1.

A verification experiment on the height of the ring nozzle 33 will be explained below.

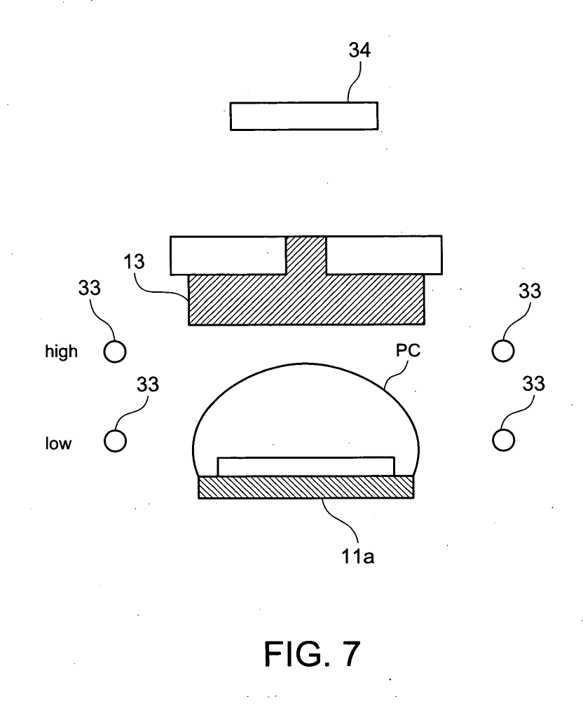

FIG. 7 is a diagram showing the outline of the verification experiment.

In the verification experiment, film deposition was carried out with the diameters of the anode 11a and the, cathode 13 set to 160 mm, the thicknesses thereof set to 15 mm, the distance between the anode 11a and the cathode 13 set to 60 mm, the inside diameter of the ring nozzle 33 set to 305 mm, the pipe diameter thereof set to 0.25 inch, the distance between the bottom side where the ejection ports of the gas shower nozzle 34 are located and the bottom side of the cathode 13 being set to 260 mm, the flow rate of hydrogen in the matrix gas discharged from the gas shower nozzle 34 being set to 600 sccm, the flow rate of argon in the matrix gas set to 48 sccm, the flow rate of methane in the reaction gas set to 60 sccm, the gas pressure set to 60 Torr, the current between the cathode 13 and the anode 11a set to 16 A, a silicon substrate having a square shape with one side of 75 mm and a thickness of 0.7 mm being used as the substrate 1, and the deposition time set to 2 hours while changing the height of the ring nozzle 33. As shown in FIG. 7, the position of the ejection ports 33a of the ring nozzle 33 lying below the bottom side of the cathode 13 by 10 mm is a position high, and the position of the ejection ports 33a lying above the top surface of the anode 11a is a position low.

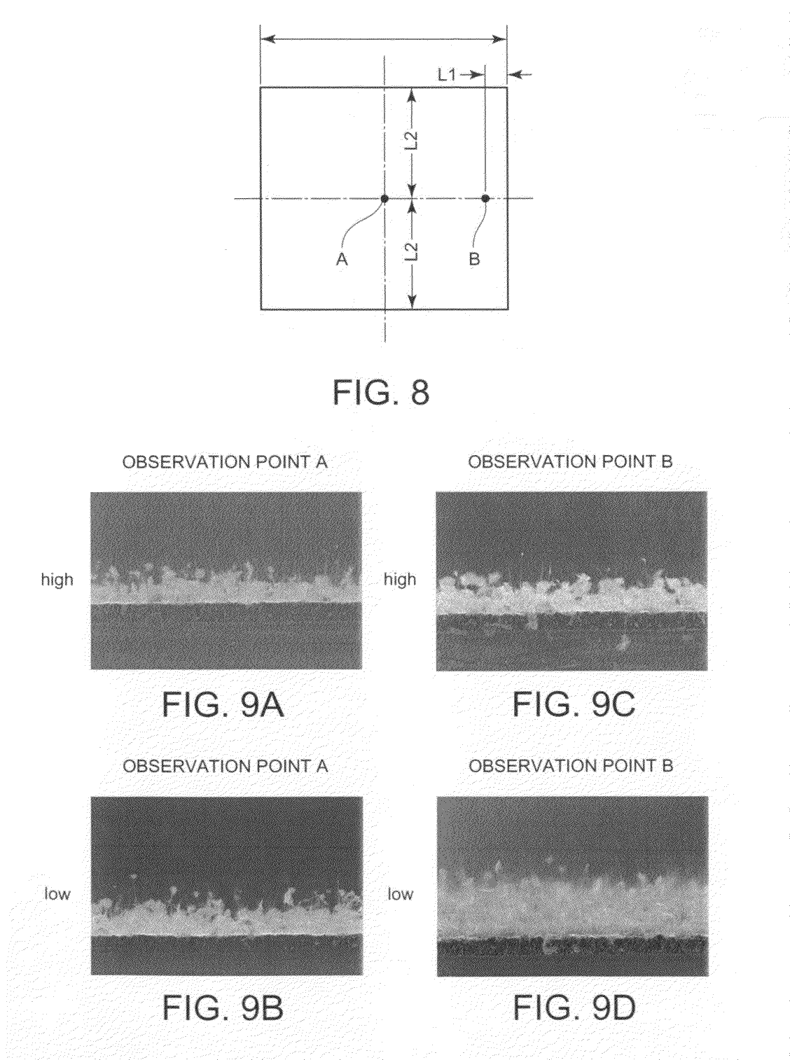

FIGS. 8 and 9 are diagrams for explaining the results of the verification experiment. In the verification experiment, the growth of a carbon nanowall was observed at an observation point A positioned in the center of the substrate 1 and on the axis 11x and an observation point B having a distance L1 of 10 mm from one end face and a distance L2 of 37.5 mm from two end faces adjacent to the former end face.

The growth of a carbon nanowall on the substrate 1 was observed in both of a case where the reaction gas was discharged from the position high and a case where the reaction gas was discharged from the position low.

FIGS. 9A and 9C are tomographic SEM images showing the growth of a carbon nanowall at the observation point A and observation point B, respectively, when plasma CVD was executed for two hours with the ejection ports 33a of the ring nozzle 33 being at the position high. FIGS. 9B and 9D are tomographic SEM images showing the growth of a carbon nanowall at the observation point A and observation point B, respectively, when plasma CVD was executed for two hours with the ejection ports 33a of the ring nozzle 33 being at the position low.

As shown in FIGS. 9A and 9C, when the reaction gas reaction gas was discharged only from the position high, the degrees of the growth of a carbon nanowall at the observation point A and the observation point B did not have a much difference. When the reaction gas reaction gas was discharged only from the position low, there was a difference between the degrees of the growth of a carbon nanowall as shown in FIGS. 9B and 9D; the carbon nanowall grew larger at the observation point B than at the observation point A.

The causes for the difference seems to that at the position low, the reaction gas ejected from the ring nozzle 33 is positioned too low and is difficult to reach the observation point A as compared with the case of the position high, and makes the temperature at the peripheral portion in the plasma, located outward of the center portion, lower than the temperature at the center portion, thereby increasing the difference between the gas temperatures at the center portion and the peripheral portion in the plasma. A drop in the gas temperature in the plasma at a portion close to the outer surface of the substrate 1 leads to an increase in the density of the active species having a relatively low chemical potential, causing non-uniform film deposition.

At the position high, on the other hand, the low-temperature reaction gas is not directly sprayed onto the positive column PC, so that the temperature gradient in the gas is small and non-uniform film deposition does not occur.

A description will now be given of an experiment of observing the state of film deposition while changing the diameter of the ejection ports 33a.

The position of the ring nozzle 33 was set to the position high shown in FIG. 7, and a change in emissivity at the top surface of the substrate was measured while changing the diameter of the ejection ports 33a to 0.5 mm, 1.0 mm and 1.5 mm. In case where depositing a graphite structure like a carbon nanowall on a silicon substrate, the emissivity generally tends to become higher as the film thickness becomes larger. The flow rates of the reaction gas per unit time are set identical by setting the moving speed of the gas immediately after ejection with the diameter of the ejection ports 33a being 0.5 mm to 500 cm/s, the moving speed of the gas immediately after ejection with the diameter of the ejection ports 33a being 1.0 mm to 125 cm/s, and the moving speed of the gas immediately after ejection with the diameter of the ejection ports 33a being 1.5 mm to 55 cm/s.

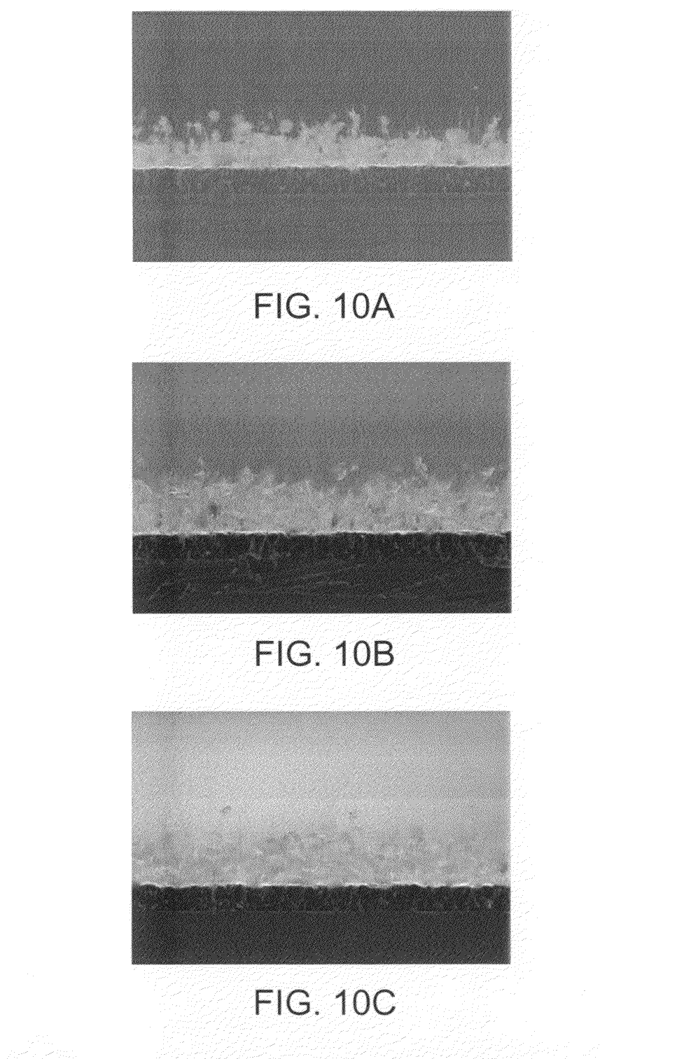

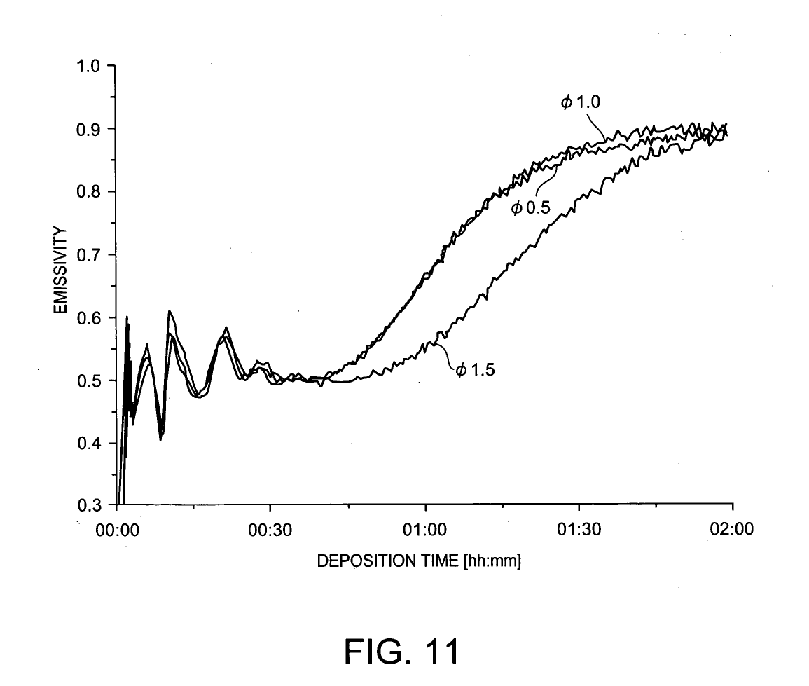

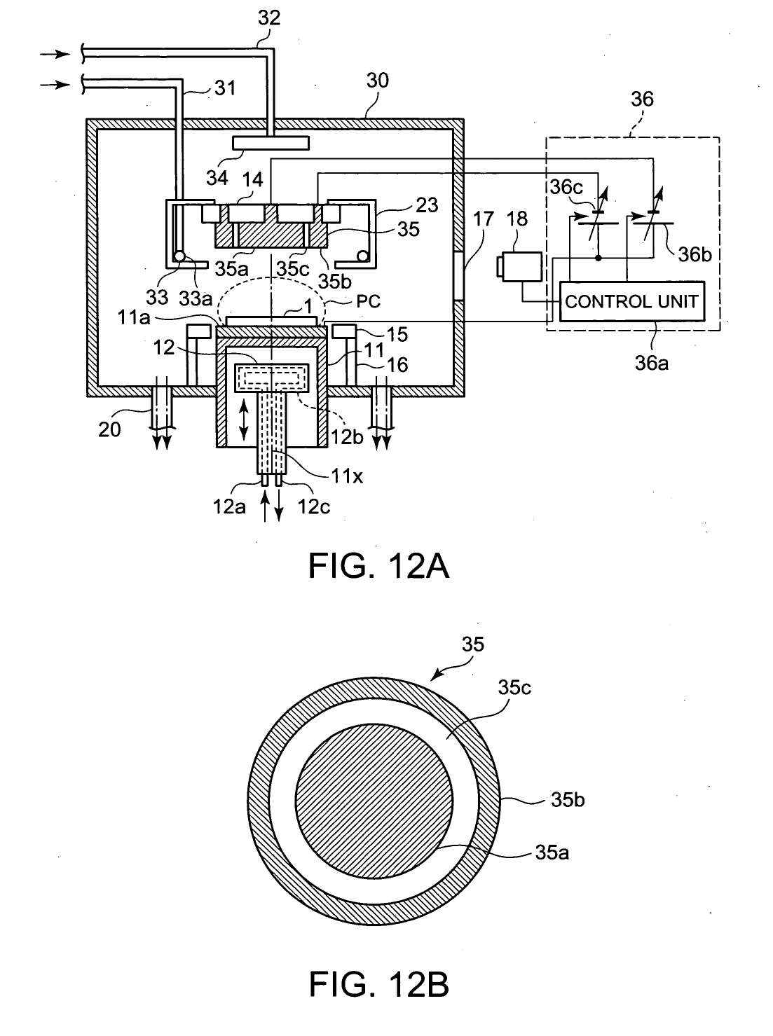

FIGS. 10A, 10B and 10C are tomographic SEM images showing the states of the film deposition at the observation point A (center of the substrate) shown in FIG. 8 when plasma CVD was executed for two hours by the plasma CVD apparatus with the diameter of the ejection ports 33a of the ring nozzle 33 being set to 0.5 mm, 1.0 mm and 1.5 mm at the position high. FIG. 11 is a diagram showing the emissivity at the substrate 1 with the diameter of the ejection ports 33a being set to 0.5 mm, 1.0 mm and 1.5 mm.

The tomographic SEM images showed that there was not a large difference in the growth of the carbon nanowall in the direction normal to the substrate at the observation points A and B in any of the cases where the diameter of the ejection ports 33a was 0.5 mm, the diameter of the ejection ports 33a was 1.0 mm, and the diameter of the ejection ports 33a was 1.5 mm. However, it is apparent from the comparison of the tomographic SEM images at the observation point A in the cases where the diameter of the ejection ports 33a is 0.5 mm (φ0.5), 1.0 mm (φ1.0), and 1.5 mm (φ1.5), the growths of the carbon nanowall in the direction normal to the substrate with φ1.0 and φ1.5 are greater than the growth of the carbon nanowall in the direction normal to the substrate with φ0.5.

It is apparent from FIG. 11 that a change in the emissivity of the substrate hardly changed between φ0.5 and φ1.0 and reached the plateau after one hour and 30 minutes whereas with φ1.5, an increase in emissivity with the growth of the carbon nanowall showed a tendency of becoming slower. Such an increase in emissivity depends on the density of the graphite component constituting the carbon nanowall on the top surface of the substrate.

It is known that the growth of the carbon nanowall in the direction normal to the substrate get faster as the amount of the active species perpendicularly directed toward the substrate 1 becomes larger. With φ0.5, the emissivity reaches the plateau faster and the height of the carbon nanowall is lower as compared with the cases of φ1.0 and φ1.5, so that the ratio of the speed of the lateral growth seems to be greater than those in the cases of φ1.0 and φ1.5. This implies that the lateral speed component of the flow of the active species formed by plasma with φ0.5 is greater than those of the other two cases and the ejection speed of the methane gas is too fast so that the flow of the gas passing through the positive column PC of the plasma is slightly disturbed.

In the case of φ1.5, the height of the carbon nanowall in the direction normal to the substrate with the deposition time of two hours hardly changes from the heights of the carbon nanowall in the direction normal to the substrate with the deposition time of two hours with φ0.5 and φ1.0, but the speed of the emissivity reaching the plateau is slower than the speeds in the other two cases and the growth of the carbon nanowall in the direction normal to the substrate is approximately equal to that in the case of φ1.0, which implies that the deposition speed of the entire graphite component is slower than those in the cases of φ0.5 and φ1.0 and the speed of the lateral growth of the carbon nanowall becomes slower accordingly. This seems to be because the ejection speed of the reaction gas is slow so that the convection of the reaction gas is not disturbed much, while the amount of the reaction gas reaching the center of the plasma is less than those in the cases of φ0.5 and φ1.0.

That is, the carbon nanowall formed with φ0.5 has a higher density per unit area of the substrate than the carbon nanowall formed with φ1.5 but has a slower growth in the direction normal to the substrate. The carbon nanowall formed with φ1.5 has a faster growth in the direction normal to the substrate than the carbon nanowall formed with φ0.5 but is slower for its density per unit area of the substrate to become sufficiently high. However, the carbon nanowall formed with φ1.5 grows to a sufficient density when the deposition time reaches two hours.

In the embodiment, therefore, it is desirable that the moving speed of the reaction gas immediately after ejection from the ring nozzle 33 be 125 cm/s or so (nozzle with φ1.0) for uniform growth of the carbon nanowall, and it is desirable that the moving speed of the reaction gas be 55 cm/s or so (nozzle with φ1.5) to 125 cm/s or so (nozzle with φ1.0) to acquire a good electron discharge characteristic with slightly poor uniformity though.

The DC plasma CVD apparatus according to the embodiment has the following advantage (7) in addition to the advantages of the first embodiment.

(7) It is generally known that the concentration of the reaction gas with respect to the matrix gas influences the film quality. However, in a method of introducing a gas mixture having a reaction gas and a matrix gas merely mixed to a predetermined concentration and supplying the gas mixture to the substrate by the conviction produced naturally, a part of the gas mixture newly introduced is discharged from the exhaust conduits 20 before the gas mixture sufficiently reaches over the substrate 1, so that the concentration of the reaction gas over the substrate 1 may become less than its concentration in the introduced gas mixture. If the concentration of the reaction gas in the gas mixture is increased to avoid that, reaction-gas oriented deposits are likely to occur on the cathode 13 and the cathode support 14 supporting the cathode 13, causing the plasma to turn into arc discharge or sparks. The DC plasma CVD apparatus of the embodiment introduces the matrix gas and the reaction gas independently, sets the ejection position of the reaction gas relatively higher with respect to the substrate 1 and sets the ejection position of the matrix gas higher than the ejection position of the reaction gas, so that the flow of the reaction gas toward the substrate 1 can be manipulated by the down force of the matrix gas, thereby reducing the amount of the reaction gas which is discharged wastefully. In addition, the ejection position of the matrix gas is set above the cathode 13 and the cathode support 14 supporting the cathode 13 and the ejection position of the reaction gas is set below the bottom side of the cathode 13, so that the down force is applied while the matrix gas reaches the exhaust conduits 20, suppressing the counterflow of the reaction gas toward the cathode 13 against the flow of the matrix gas and preventing the reaction gas component from being adhered to the cathode 13 and the cathode support 14 supporting the cathode 13.

### Fourth Embodiment

FIGS. 12A and 12B are configuration diagrams of a DC plasma CVD apparatus according to a fourth embodiment of the present invention. Common reference numerals are given to those components in FIGS. 12A and 12B which are common to the components in FIG. 6.

This DC plasma CVD apparatus is the DC plasma CVD apparatus in FIG. 1 whose cathode 13 is changed to a cathode 35 and whose voltage setting unit 21 is changed to a voltage setting unit 36.

The cathode 35 has a center electrode 35a facing the center portion of the anode 11a, a peripheral electrode 35b which is shaped like a ring (see FIG. 12B) surrounding the center electrode 35a, is concentric to the center electrode 35a and faces the peripheral portion of the anode 11a, and an insulating part 35c of ceramics or the like fully filled between the center electrode 35a and the peripheral electrode 35b.

Without the insulating part 35c intervening between the center electrode 35a and the peripheral electrode 35b, a film which grows by the active species is deposited not only on the substrate 1 but also on the side wall of the center electrode 35a and the side wall of the peripheral electrode 35b facing each other. In this respect, the insulating part 35c is intervened to prevent a film from being deposited on the side wall of the center electrode 35a and the side wall of the peripheral electrode 35b facing each other.

The voltage setting unit 36 has a control unit 36a, and variable power sources 36b, 36c.

The control unit 36a is connected to the radiation thermometer 18 by a lead line. The control unit 36a has a capability of controlling the variable power sources 36b, 36c and individually setting the voltage or current between the anode 11a and the center electrode 35a and the voltage or current between the anode 11a and the center electrode 35b. The other configuration is the same as that of the DC plasma CVD apparatus in FIG. 6.

In case where a film is formed on the substrate 1 using the DC plasma CVD apparatus in FIGS. 12A and 12B, the substrate 1 is rotated at 1 rpm at the rising of plasma, the voltage between the anode 11a and the center electrode 35a is made greater than the voltage between the anode 11a and the peripheral electrode 35b under the control of the voltage setting unit 36 to set the voltage between the cathode 35 and the anode 11a. Such voltage application produces a small positive column PC between the anode 11a and the center electrode 35a, and can prevent occurrence of arc discharge at the initial stage of film deposition.

After the stable positive column PC is formed at the upper portion of the center portion of the substrate 1 by such application of the voltage or current, the control unit 36a applies the voltage or current in such a way that the value of the voltage or current between the anode 11a and the center electrode 35a becomes less than the value of the voltage or current between the anode 11a and the peripheral electrode 35b to approximate the temperature between the anode 11a and the center electrode 35a to the temperature between the anode 11a and the peripheral electrode 35b or make those temperatures approximately identical before performing film deposition on the substrate 1.

In the embodiment, as described above, the cathode 35 comprises the center electrode 35a and the peripheral electrode 35b, and the value of the voltage or current between the anode 11a and the center electrode 35a and value of the voltage or current between the anode 11a and the peripheral electrode 35b can be independently set. At the rising of plasma, the voltage between the anode 11a and the center electrode 35a is set higher than the voltage between the anode 11a and the peripheral electrode 35b. Accordingly, the positive column PC can be formed with the distance between the anode 11a and the cathode 35 made shorter. The voltage to be applied to the anode 11a and the cathode 35 can be low, thereby suppressing the frequent occurrence of arc discharge or sparking.

Further, the current flowing across the peripheral electrode 35b is made smaller than the current flowing across the center electrode 35a to produce a positive column PC concentrated on the center of the substrate 1, after which the power to be applied to the peripheral electrode 35b is increased to increase the current flowing across the peripheral electrode 35b. This makes it possible to prevent local arc discharge which occurs at the initial stage of film deposition after which the positive column PC can be grown to the necessary size.

### Fifth Embodiment

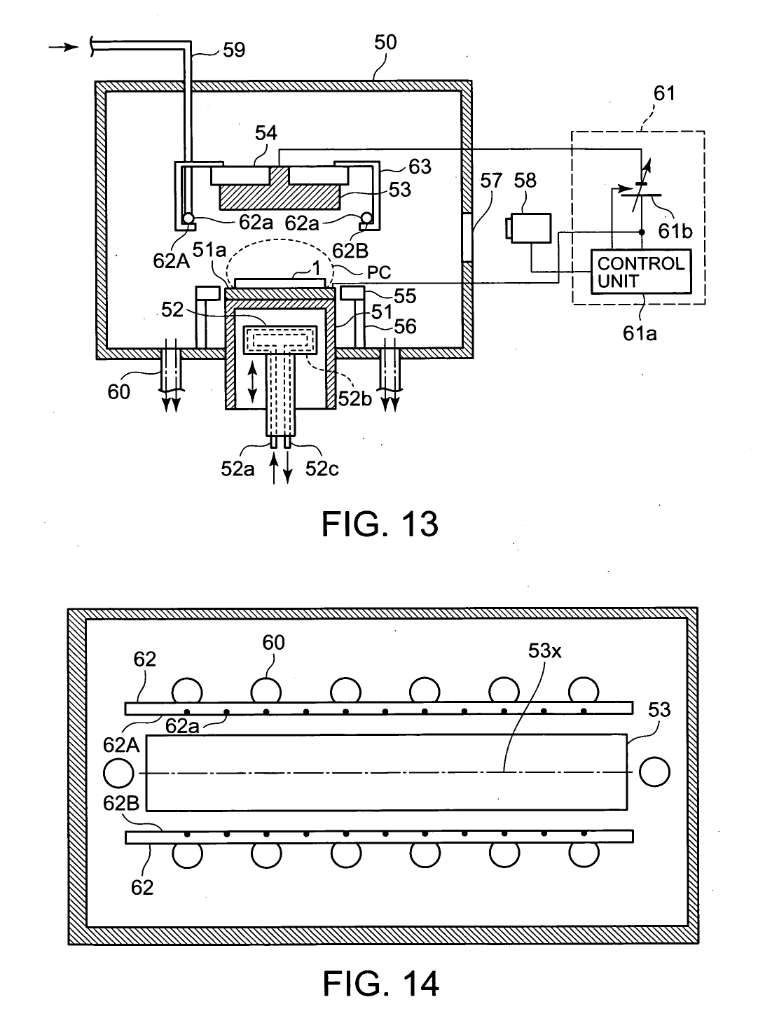

FIG. 13 is a configuration diagram showing a DC plasma CVD apparatus according to a fifth embodiment of the present invention.

FIG. 14 is a schematic diagram showing a cathode, a source gas nozzle and exhaust conduits of the DC plasma CVD apparatus in FIG. 13 from above.

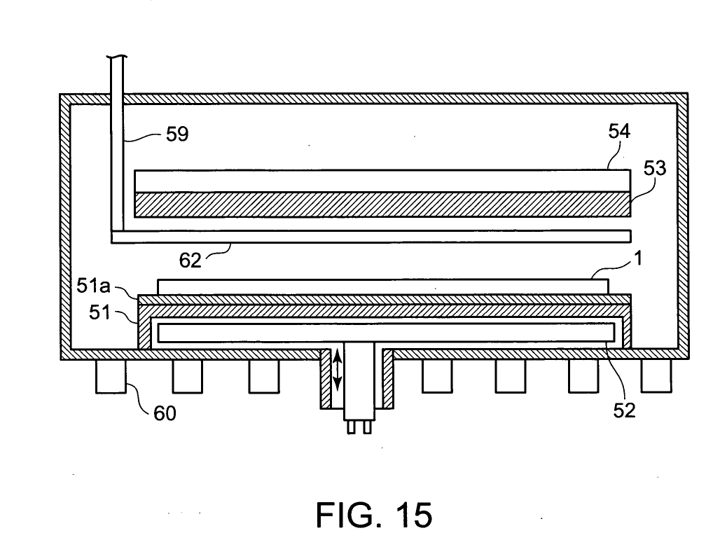

FIG. 15 is a cross-sectional view showing the DC plasma CVD apparatus in FIG. 13 from sideward.

The DC plasma CVD apparatus forms a film on the top surface of a substrate 1 to be processed, and has a chamber 50 as a reacting furnace. The chamber 50 shields the substrate 1 from the outside air.

A rectangular parallelepiped steel stage 51 is disposed in the chamber 50. A rectangular-plate shaped anode 51a with a of a material having a high thermal conductivity and a high melting point, such as molybdenum or graphite, is mounted on the stage 51. The substrate 1 is fixed on an upper mount surface of the anode 51a. The substrate 1 may have a rectangular shape or a plurality of square substrates 1 may be placed on the anode 51a.

The stage 51 underlying the anode 51a is provided with closed space 51b where a cooling member 52 is disposed. The cooling member 52 is provided to cool down the substrate 1 as needed, and is configured to be movable up and down as indicated by arrows by a moving mechanism (not shown). The cooling member 52 is formed of a metal having a high thermal conductivity, such as copper. A coolant, such as cooled water or a cooled solution of calcium chloride, enters a flow passage 52b in the cooling member 52 from a conduit 52a and is discharged from a conduit 52c to circulate in the cooling member 52 to cool the whole cooling member 52.

As the cooling member 52 moves upward, the top side of the cooling member 52 buts on the bottom side of the stage 51 which cools the overlying anode 51a that in turn takes heat away from the substrate 1. The top side of the cooling member 52 is rectangular and cools the entire stage 51 in the lengthwise direction.

The coolant discharged from the conduit 52c is cooled by the cooling unit (not shown) and is sent again to the conduit 52a for recirculation.

The space 51b provided under the anode 51a is partitioned by the stage 51, so that the interior of the space 51b is filled with a gas or is open to the air.

A rectangular-plate shaped cathode 53 is disposed above the anode 51a. The cathode 53 is supported on a cathode support 14 and faces the anode 51a. The cathode 53 is formed of molybdenum, graphite or the like having a high melting point.

The cathode support 54 is made of a heat-resistant oxide, such as quartz glass or alumina, a heat-resistant nitride, such as aluminum nitride or silicon nitride, or a heat-resistant carbide, such as silicon carbide.

A passage where the coolant flows may be formed in the cathode 53. The flow of the coolant can suppress overheating of the cathode 53. Preferable coolants are water, calcium chloride solution and the like which are supplied from outside the chamber 50.

An insulating unit 55 for suppressing occurrence of arcs is disposed near the outer surface of the anode 51a. The insulating unit 55 comprises at least one of a heat-resistant oxide, such as quartz glass or alumina, a heat-resistant nitride, such as aluminum nitride or silicon nitride, and a heat-resistant carbide, such as silicon carbide.

The insulating unit 55, which has an annular shape, is supported at the same height as the anode 51a by a support 16 provided upright at the bottom portion of the chamber 50 and its inner side surrounds the anode 51a.

Because the insulating unit 55 serves to suppress occurrence of abnormal discharge (arc discharge, sparking) between the cathode 53 and the anode 51a, the insulating unit 55 is disposed along the outer surface of the anode 51a and opposite the cathode 53. The insulating unit 55 may be arranged to hide the side faces of the anode 51a.

A window 57 is formed in the side face of the chamber 50 to permit observation of the interior of the chamber 50. A heat-resistant glass is fitted in the window 57 to secure the airtightness inside the chamber 50. A radiation thermometer 58, which measures the temperature of the substrate 1 via, for example, the window 57, is disposed outside the chamber 50.

The DC plasma CVD apparatus has a source system (not shown) which supplies a source gas containing a reaction gas through a gas tube 59, an exhaust system (not shown) which discharges a gas from inside the chamber 50 through exhaust conduits 60, and a voltage setting unit 61.

The gas tube 59 is inserted into the chamber 50 through a hole provided in the chamber 50, and at least a part of the gas tube 59 in the reacting furnace is formed by an insulator, such as fluororesin or silicon gum. A sealant seals between the hole of the chamber 50 and the outer surface of the gas tube 59 to secure the airtightness inside the chamber 50. In the chamber 50, the gas tube 59 is connected to a nozzle 62 which is a gas supply nozzle.

The nozzle 62 has a portion 62A parallel to one long side of each of the anode 51a and the cathode 53 and a portion 62B parallel to the other long side of each of the anode 51a and the cathode 53. The nozzle 62 may be annular entirely, or the portions 62A, 62B may be branched from the point of connection to the gas tube 59. The nozzle 62 is hollow to pass the source gas. A plurality of ejection ports 62a are formed in the portions 62A, 62B of the nozzle 62 at equal intervals in line symmetrical with respect to an axis 53x or the center axis along the long-side lengthwise direction of the cathode 53, so that the source gas is ejected from the ejection ports 62a toward the substrate 1 laterally, i.e., in the lateral inward direction.

The nozzle 62 is supported by an insulator nozzle support 63 attached to the cathode support 54. The support height of the nozzle 62 is set in such a way that the ejection ports 62a are set below the lowermost portion of the cathode support 54 (topmost portion of an exposed side face of the cathode 53) and at a position higher than the highest point of a positive column PC formed between the anode 51a and the cathode 53. As the nozzle 62 is supported in this range, the source gas easily enters between the cathode 53 and the anode 51a, and can prevent the gas temperature in the positive column PC from being locally cooled by ejection of the source gas.

The interval between the portions 62A, 62B of the nozzle 62 is greater than the width of the cathode 53 (short-side direction), and the portions 62A, 62B of the nozzle 62 are positioned further outward of both side faces of the cathode 53 in the long-side direction. The portions 62A, 62B are approximately at equal distances from the center line of the anode 51a in the long-side direction.

The exhaust conduits 60 respectively penetrate a plurality of holes formed in the bottom side of the chamber 50 at equal intervals to surround the stage 51. A sealant seals between each hole and the outer surface of the associated exhaust conduit 60.

The voltage setting unit 61 is a control device that sets the value of a voltage or current between the anode 51a and the cathode 53 and has a control unit 61a and a variable power source 61b. The voltage setting unit 61 is connected to the anode 51a and the cathode 53 by lead lines. The lead lines pass through holes provided in the chamber 50. The holes in the chamber 50 where the lead lines pass are sealed by a sealant.

The control unit 61a of the voltage setting unit 61 is connected to the radiation thermometer 58 by a lead line and to the variable power source 61b by a lead line. When activated, the control unit 61a refers to the temperature of the substrate 1 measured by the radiation thermometer 58, and adjusts the value of the voltage or current between the anode 51a and the cathode 53 so that the temperature of the substrate 1 becomes a predetermined value.

Next, a description will be given of a deposition process which forms a film on the substrate 1 using the DC plasma CVD apparatus in FIG. 13.

In the deposition process, an electron discharge film comprising a carbon nanowall is deposited on the top surface of the substrate 1.

In the deposition process, first, a nickel plate, for example, is cut out as the substrate 1 and is substantially subjected to degreasing/ultrasonic cleaning with ethanol or acetone.

This substrate 1 is placed on the anode 51a.

When mounting the substrate 1 is completed, next, the chamber 50 is depressurized by using the exhaust system, and a hydrogen gas and a reaction gas and a reaction gas (carbon contained compound) of a compound containing a carbon in a composition, such as methane, are supplied into the chamber 50 from the gas tube 59. The source gas is ejected from the ejection ports 62a of the nozzle 62.

At the time of depositing a carbon nanowall, film deposition is performed at a temperature of 900° C. to 1100° C. set as the temperature of that portion of the substrate 1 where the carbon nanowall is formed. This temperature is measured by the radiation thermometer 58. At this time, the cooling member 52 is separated substantially from the anode 51a to avoid influence on the temperature of the anode 51a. The radiation thermometer 58 is so set as to decrease the plasma radiation of the DC plasma CVD apparatus and acquire the temperature only from the heat radiation at the top surface of the substrate 1.

When a diamond layer containing multiple diamond particles is laminated on the carbon nanowall while changing the film property of the electron discharge film during the carbon nanowall deposition process, for example, the cooling member 52 is moved upward to abut on the anode 51a. Accordingly, the temperature of the substrate 1 can be significantly lowered to enable lamination of the diamond layer. As the diamond layer grows, sp² bonded carbon of a rod shape, which is a modified part of the carbon nanowall, and, unlike a carbon nanotube, having a filled core, grows. This rod-shaped carbon extends to protrude from the top surface of the diamond layer, and is a portion on which structurally an electric field is likely to be concentrated and which discharges electrons.

At the end stage of film deposition, application of the voltage between the anode 51a and the cathode 53 is stopped, then the supply of the source gas is stopped and a nitrogen gas is supplied into the chamber 50 as a purge gas to provide a nitrogen atmosphere in the chamber 50, after which the substrate 1 is removed with the temperature returned to normal temperature.

The DC plasma CVD apparatus according to the embodiment has the following advantages (8) and (9) in addition to the advantages (1) to (6) of the first embodiment.

(8) To made film deposition on the substrate 1 having a large area, it is necessary to increase the areas (outside diameters) of the stage 11 and the cathode 13 in the DC plasma CVD apparatus of the first embodiment. Increasing the areas (outside diameters) of the stage 11 and the cathode 13 may however result in an insufficient reaction gas to be supplied to the center of the stage 11 or may cause an non-negligible temperature difference between the peripheral side and the center portion. This is likely to cause a variation in film deposition.

In the DC plasma CVD apparatus of the fifth embodiment, by way of contrast, the stage 51 and the cathode 53 have rectangular shapes and the portions 62A, 62B of the nozzle 62 are disposed in parallel to the long-side direction. This can ensure supply of the source gas which does not vary in the long-side direction, thus making it possible to suppress a variation in film deposition in the long-side direction. Adequately setting the lengths of the anode 51a and the cathode 53 in the short-side direction can ensure variation-suppressed film deposition on the substrate 1 having a large area.

(9) Because the stage 51 and the cathode 53 have rectangular shapes, a plurality of square substrates 1 can be disposed in the long-side direction of the anode 51a and the cathode 53, so that simultaneous film deposition can be performed on a plurality of substrates 1 at a time. This is suitable for mass production. In this case, film deposition is performed on a plurality of substrates 1 in the same lot, so that if film deposition is performed on a necessary number of substrates, there is no need to consider a variation between lots.

### Sixth Embodiment

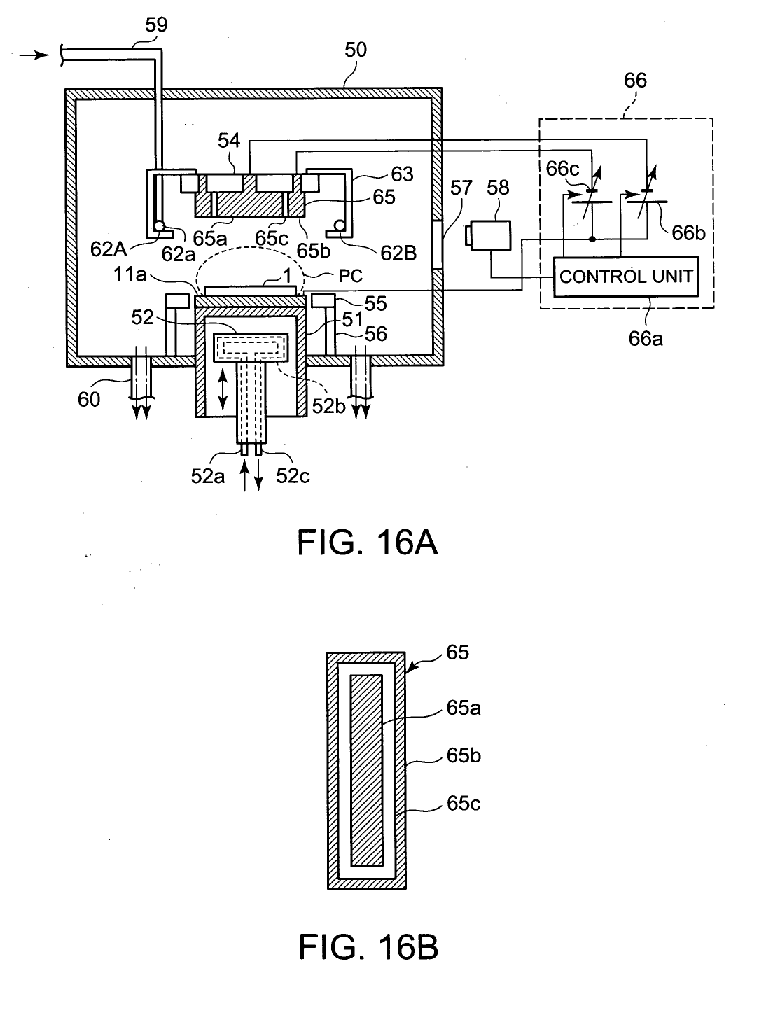

FIG. 16A is a configuration diagram of a DC plasma CVD apparatus according to a sixth embodiment of the present invention, and FIG. 16B is a plan view of the cathode as seen from below.

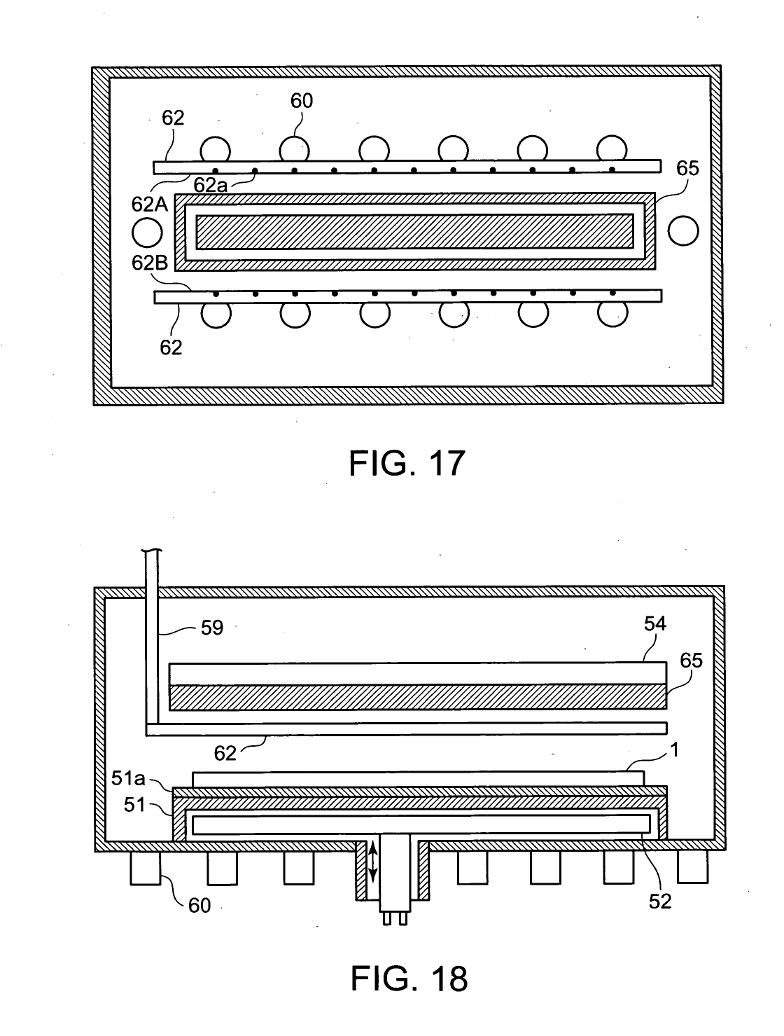

FIG. 17 is a diagram showing a cathode, a source gas nozzle and exhaust conduits of the DC plasma CVD apparatus in FIG. 16A from above.

FIG. 18 is a cross-sectional view showing the DC plasma CVD apparatus in FIG. 16A from sideward.

This DC plasma CVD apparatus is the DC plasma CVD apparatus of the fifth embodiment shown in FIG. 13 whose cathode 53 is changed to a cathode 65 and whose voltage setting unit 61 is changed to a voltage setting unit 66.

The cathode 65 has a center electrode 65a facing the center portion of the anode 51a, a peripheral electrode 65b which has an annular shape ring (see FIG. 16B) surrounding the center electrode 65a, and faces the peripheral portion of the anode 51a, and an insulating part 65c of ceramics or the like fully filled between the center electrode 65a and the peripheral electrode 65b.

Without the insulating part 65c intervening between the center electrode 65a and the peripheral electrode 65b, a film which grows by the active species is deposited not only on the substrate 1 but also on the side wall of the center electrode 65a and the side wall of the peripheral electrode 65b facing each other. In this respect, the insulating part 65c is intervened to prevent a carbon film from being deposited on the side wall of the center electrode 65a and the side wall of the peripheral electrode 65b facing each other.

The voltage setting unit 66 has a control unit 66a, and variable power sources 66b, 66c.

The control unit 66a is connected to the radiation thermometer 18 by a lead line. The control unit 66a has a capability of controlling the variable power sources 66b, 66c and individually setting the voltage or current between the anode 51a and the center electrode 65a and the voltage or current between the anode 51a and the center electrode 65b. The other configuration is the same as that of the DC plasma CVD apparatus in FIG. 13.

In case where a film is formed on the substrate 1 using the DC plasma CVD apparatus in FIGS. 16A and 16B, at 1 rpm at the rising of plasma, the voltage difference between the stage 51 and the center electrode 65a is made greater than the voltage difference between the stage 51 and the peripheral electrode 65b under the control of the voltage setting unit 66 to set the voltage between the cathode 65 and the anode 51a. Such voltage application produces a small positive column PC between the anode 51a and the center electrode 65a, and can prevent occurrence of arc discharge at the initial stage of film deposition.

After the stable positive column PC is formed at the upper portion of the center portion of the substrate 1 by such application of the voltage or current, the control unit 66a applies the voltage or current in such a way that the value of the voltage or current between the anode 51a and the-center electrode 65a becomes less than the value of the voltage or current between the anode 51a and the peripheral electrode 65b to approximate the temperature between the anode 51a and the center electrode 65a to the temperature between the anode 51a and the peripheral electrode 65b or make those temperatures approximately identical before performing film deposition on the substrate 1.

In the embodiment, as described above, the cathode 65 comprises the center electrode 65a and the peripheral electrode 65b, and the value of the voltage or current between the anode 51a and the center electrode 65a and value of the voltage or current between the anode 51a and the peripheral electrode 65b can be independently set. At the rising of plasma, the voltage between the anode 51a and the center electrode 65a is set higher than the voltage between the anode 51a and the peripheral electrode 65b. Accordingly, the positive column PC can be formed with the distance between the anode 51a and the cathode 65 made shorter. The voltage to be applied to the anode 51a and the cathode 65 cab be low, thereby suppressing the frequent occurrence of arc discharge or sparking.

Further, the current-flowing across the peripheral electrode 65b is made smaller than the current flowing across the center electrode 65a to produce a positive column PC concentrated on the long-side center of the substrate 1, after which the power to be applied to the peripheral electrode 65b is increased to increase the current flowing across the peripheral electrode 65b. This makes it possible to prevent local arc discharge which occurs at the initial stage of film deposition after which the positive column PC can be grown to the necessary size.

### Seventh Embodiment

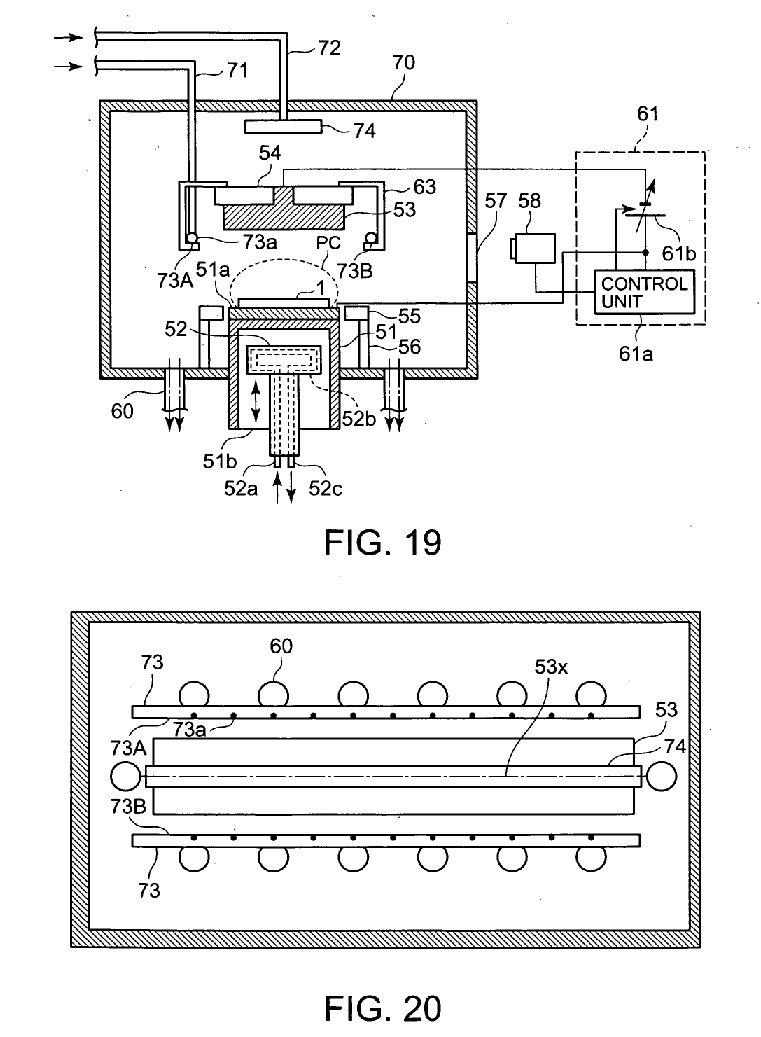

FIG. 19 is a configuration diagram showing a DC plasma CVD apparatus according to a seventh embodiment of the present invention, and common reference numerals are given to those components in FIG. 19 which are common to the components in FIG. 13.

FIG. 20 is a schematic diagram showing a cathode, a reaction gas nozzle, a matrix gas and nozzle, and exhaust conduits of the DC plasma CVD apparatus in FIG. 19 from above.

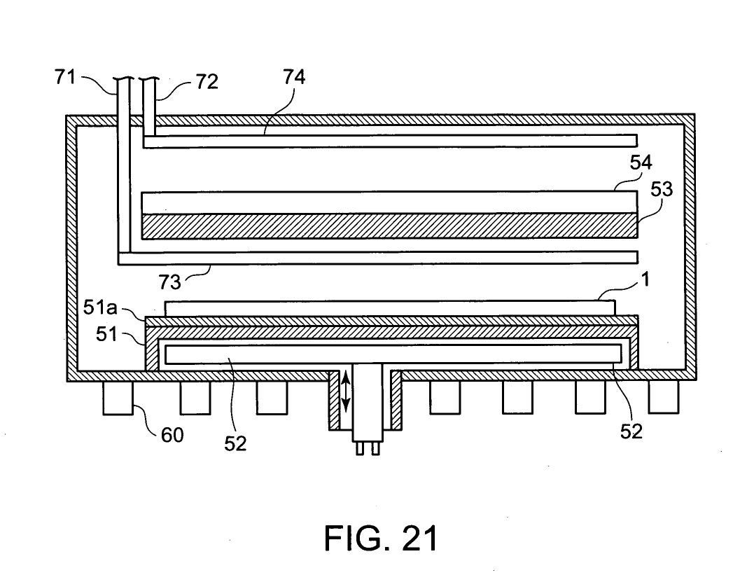

FIG. 21 is a cross-sectional view showing the DC plasma CVD apparatus in FIG. 19 from sideward.

The DC plasma CVD apparatus forms a film on the top surface of a substrate 1 to be processed, and has a chamber 70 as a reacting furnace. The chamber 70 shields the substrate 1 from the outside air.

A rectangular parallelepiped steel stage 51 is disposed in the chamber 70. A rectangular-plate shaped anode 51a with a of a material having a high thermal conductivity and a high melting point, such as molybdenum or graphite, is mounted on the stage 51. The substrate 1 is fixed on an upper mount surface of the anode 51a. The substrate 1 may have a rectangular shape or a plurality of square substrates 1 may be placed on the anode 51a.

The stage 51 underlying the anode 51a is provided with closed space 51b where a cooling member 52 is disposed. The cooling member 52 is provided to cool down the substrate 1 as needed, and is configured to be movable up and down as indicated by arrows by a moving mechanism (not shown). The cooling member 52 is formed of a metal having a high thermal conductivity, such as copper. A coolant, such as cooled water or a cooled solution of calcium chloride, enters a flow passage 52b in the cooling member 52 from a conduit 52a and is discharged from a conduit 52c to circulate in the cooling member 52 to cool the whole cooling member 52.

As the cooling member 52 moves upward, the top side of the cooling member 52 buts on the bottom side of the stage 51 which cools the overlying anode 51a that in turn takes heat away from the substrate 1. The top side of the cooling member 52 is rectangular and cools the entire stage 51 in the lengthwise direction.

The coolant discharged from the conduit 52c is cooled by the cooling unit (not shown) and is sent again to the conduit 52a for recirculation.

The space 51b provided under the anode 51a is partitioned by the stage 51, so that the interior of the space 51b is filled with a gas or is open to the air.

A rectangular-plate shaped cathode 53 is disposed above the anode 51a. The cathode 53 is supported on a cathode support 14 and faces the anode 51a. The cathode 53 is formed of molybdenum, graphite or the like having a high melting point.

The cathode support 54 is made of a heat-resistant oxide, such as quartz glass or alumina, a heat-resistant nitride, such as aluminum nitride or silicon nitride, or a heat-resistant carbide, such as silicon carbide.

A passage where the coolant flows may be formed in the cathode 53. The flow of the coolant can suppress overheating of the cathode 53. Preferable coolants are water, calcium chloride solution and the like which are supplied from outside the chamber 70.

An insulating unit 55 for suppressing occurrence of arcs is disposed near the outer surface of the anode 51a. The insulating unit 55 comprises at least one of a heat-resistant oxide, such as quartz glass or alumina, a heat-resistant nitride, such as aluminum nitride or silicon nitride, and a heat-resistant carbide, such as silicon carbide.

The insulating unit 55, which has an annular shape, is supported at the same height as the anode 51a by a support 16 provided upright at the bottom portion of the chamber 70 and its inner side surrounds the anode 51a.

Because the insulating unit 55 serves to suppress occurrence of abnormal discharge (arc discharge, sparking) between the cathode 53 and the anode 51a, the insulating unit 55 is disposed along the outer surface of the anode 51a and opposite the cathode 53. The insulating unit 55 may be arranged to hide the side faces of the anode 51a.

A window 57 is formed in the side face of the chamber 70 to permit observation of the interior of the chamber 70. A heat-resistant glass is fitted in the window 57 to secure the airtightness inside the chamber 70. A radiation thermometer 58, which measures the temperature of the substrate 1 via, for example, the window 57, is disposed outside the chamber 70.

The DC plasma CVD apparatus has a reaction gas system (not shown) which supplies a reaction gas through a gas tube 71, a source system (not shown) which supplies a matrix gas through a gas tube 72, an exhaust system (not shown) which discharges a gas from inside the chamber 70 through exhaust conduits 60, and a voltage setting unit 61.

The gas tube 71 is inserted into the chamber 70 through a hole provided in the chamber 70, and at least a part of the gas tube 71 in the reacting furnace is formed by an insulator, such as fluororesin or silicon gum. A sealant seals between the hole of the chamber 70 and the outer surface of the gas tube 71 to secure the airtightness inside the chamber 70. In the chamber 70, the gas tube 71 is connected to a nozzle 73 which is a reaction gas supply nozzle.

The nozzle 73 has a portion 73A parallel to one long side of each of the anode 51a and the cathode 53 and a portion 73B parallel to the other long side of each of the anode 51a and the cathode 53. The nozzle 73 may be annular entirely, or the portions 73A, 73B may be branched from the point of connection to the gas tube 71. The nozzle 73 is hollow to pass the reaction gas. A plurality of ejection ports 73a are formed in the portions 73A, 73B of the nozzle 73 at equal intervals in line symmetrical, so that the source gas is ejected from the ejection ports 73a toward the substrate 1 laterally, i.e., in the lateral inward direction.

The nozzle 73 is supported by an insulator nozzle support 63 attached to the cathode support 54. The support height of the nozzle 73 is set in such a way that the ejection ports 73a are set below the lowermost portion of the cathode support 54 (topmost portion of an exposed side face of the cathode 53) and at a position higher than the highest point of a positive column PC formed between the anode 51a and the cathode 53. As the nozzle 73 is supported in this range, the source gas easily enters between the cathode 53 and the anode 51a, and can prevent the gas temperature in the positive column PC from being locally cooled by ejection of the source gas.

The interval between the portions 73A, 73B of the nozzle 73 is greater than the width of the cathode 53 (short-side direction), and the portions 73A, 73B of the nozzle 73 are positioned further outward of both side faces of the cathode 53 in the long-side direction. The portions 73A, 73B are approximately at equal distances from the center line of the anode 51a in the long-side direction.

The exhaust conduits 60 respectively penetrate a plurality of holes formed in the bottom side of the chamber 70 at equal intervals to surround the stage 51. A sealant seals between each hole and the outer surface of the associated exhaust conduit 60.

The voltage setting unit 61 is a control device that sets the value of a voltage or current between the anode 51a and the cathode 53 and has a control unit 61a and a variable power source 61b. The voltage setting unit 61 is connected to the anode 51a and the cathode 53 by lead lines. The lead lines pass through holes provided in the chamber 70. The holes in the chamber 70 where the lead lines pass are sealed by a sealant.

The control unit 61a of the voltage setting unit 61 is connected to the radiation thermometer 58 by a lead line and to the variable power source 61b by a lead line. When activated, the control unit 61a refers to the temperature of the substrate 1 measured by the radiation thermometer 58, and adjusts the value of the voltage or current between the anode 51a and the cathode 53 so that the temperature of the substrate 1 becomes a predetermined value.

The gas tube 72, which is made by an insulator, passes through a hole provided in the chamber 70. A sealant seals between the hole and the outer surface of the gas tube 72 to secure the airtightness inside the chamber 70. In the chamber 70, the gas tube 72 is connected to a gas shower nozzle 74 for a matrix gas.

The gas shower nozzle 74, which has approximately the same length as the cathode 53, is positioned above the cathode support 14 supporting the cathode 53 and above the nozzle 73 and is disposed in parallel to and in line symmetrical with respect to the axis 53x as the center axis along the long-side direction of the cathode 53 to eject the matrix gas downward like a shower.

The basic operation in performing film deposition using the DC plasma CVD apparatus of the embodiment is similar to that of the case of using the DC plasma CVD apparatus of the fifth embodiment. It is to be noted that in the DC plasma CVD apparatus of the embodiment, the matrix gas and the reaction gas are introduced independently and the reaction gas is ejected from the nozzle 73 in the lateral inward direction while the matrix gas is ejected downward from the gas shower nozzle 74. The matrix gas changes the vector of the flow of the reaction gas ejected laterally so that the reaction gas flows toward the obliquely underlying substrate 1.

The DC plasma CVD apparatus according to the embodiment has the following advantage (10) in addition to the advantages of the fifth embodiment.

(10) It is generally known that the concentration of the reaction gas with respect to the matrix gas influences the film quality. However, in a method of introducing a gas mixture having a reaction gas and a matrix gas merely mixed to a predetermined concentration and supplying the gas mixture to the substrate by the conviction produced naturally, the gas mixture newly sufficient to effect film deposition on the substrate 1 with the gas mixture newly introduced is discharged from the exhaust conduits 60 before the gas mixture sufficiently reaches over the substrate 1, so that the reaction gas may be consumed wastefully. If the concentration of the reaction gas in the gas mixture is increased to avoid that, reaction-gas oriented deposits are likely to occur on the cathode 53 and the insulating cathode support 54 supporting the cathode 53, causing the plasma to turn into arc discharge or sparks. The DC plasma CVD apparatus of the embodiment introduces the matrix gas and the reaction gas independently, sets the ejection position of the reaction gas relatively higher with respect to the substrate 1 and sets the ejection position of the matrix gas higher than the ejection position of the reaction gas, so that the flow of the reaction gas toward the substrate 1 can be manipulated by the down force of the matrix gas, thereby reducing the amount of the reaction gas which is discharged wastefully. In addition, the ejection position of the matrix gas is set above the cathode 53 and the cathode support 54 supporting the cathode 53 and the ejection position of the reaction gas is set below the bottom side of the cathode 53, so that the down force is applied while the matrix gas reaches the exhaust conduits 60, suppressing the counterflow of the reaction gas toward the cathode 53 against the flow of the matrix gas and preventing the reaction gas component from being adhered to the cathode 53 and the insulating cathode support 54 supporting the cathode 53.

### Eighth Embodiment

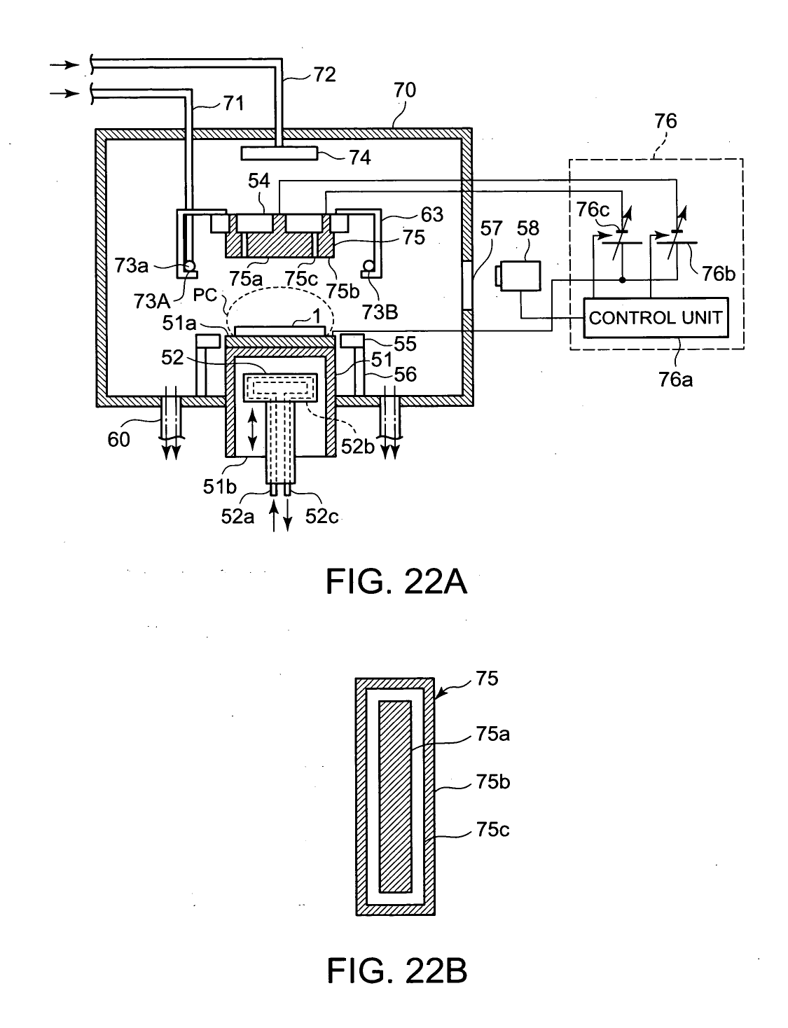

FIGS. 22A and 22B are configuration diagrams of a DC plasma CVD apparatus according to an eighth embodiment of the present invention. Common reference numerals are given to those components in FIGS. 22A and 22B which are common to the components in FIG. 19.

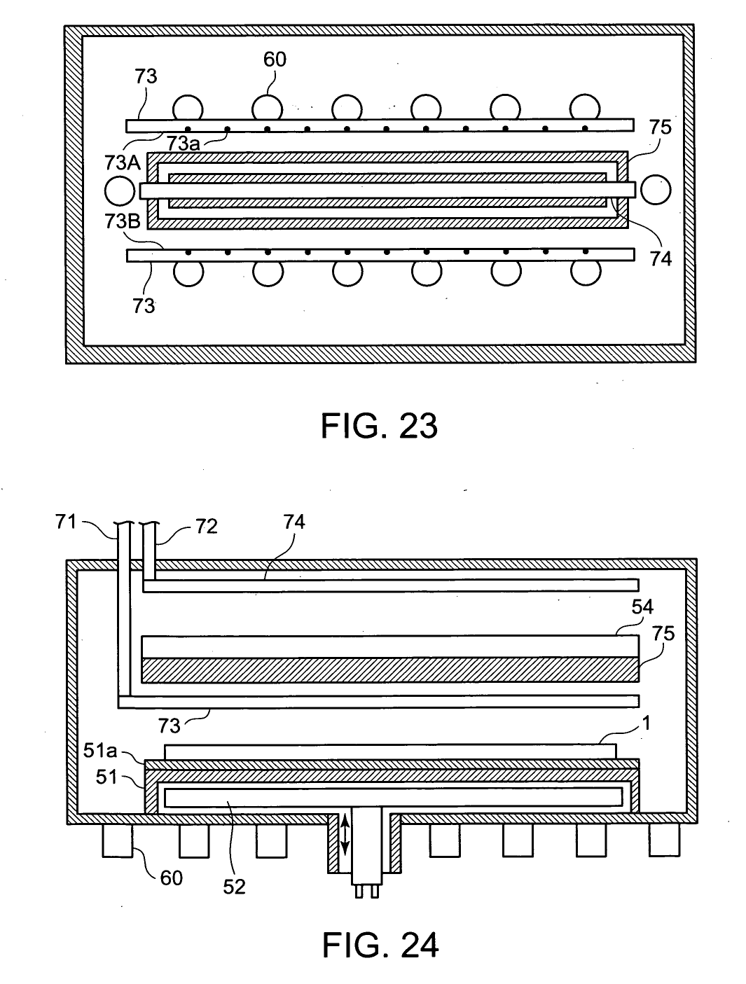

FIG. 23 is a diagram showing a cathode, a reaction gas nozzle, a matrix gas nozzle and exhaust conduits of the DC plasma CVD apparatus in FIG. 22A from above.

FIG. 21 is a cross-sectional view showing the DC plasma CVD apparatus in FIG. 22A from sideward.

This DC plasma CVD apparatus is the DC plasma CVD apparatus of the seventh embodiment shown in FIG. 19 whose cathode 53 is changed to a cathode 75 and whose voltage setting unit 61 is changed to a voltage setting unit 76.

The cathode 75 has a center electrode 75a facing the center portion of the anode 51a, a peripheral electrode 75b which has an annular shape (see FIG. 22B) surrounding the center electrode 75a, and faces the peripheral portion of the anode 51a, and an insulating part 75c of ceramics or the like fully filled between the center electrode 75a and the peripheral electrode 75b.

Without the insulating part 75c intervening between the center electrode 75a and the peripheral electrode 75b, a film which grows by the active species is deposited not only on the substrate 1 but also on the side wall of the center electrode 75a and the side wall of the peripheral electrode 75b facing each other. In this respect, the insulating part 75c is intervened to prevent a carbon film from being deposited on the side wall of the center electrode 75a and the side wall of the peripheral electrode 75b facing each other.

The voltage setting unit 76 has a control unit 76a, and variable power sources 76b, 76c.

The control unit 76a is connected to the radiation thermometer 58 by a lead line. The control unit 76a has a capability of controlling the variable power sources 76b, 76c and individually setting the voltage or current between the anode 51a and the center electrode 75a and the voltage or current between the anode 51a and the center electrode 75b. The other configuration is the same as that of the DC plasma CVD apparatus in FIG. 13.

In case where a film is formed on the substrate 1 using the DC plasma CVD apparatus in FIGS. 22A and 22B, at the rising of plasma, the voltage between the anode 51a and the center electrode 75a is made greater than the voltage between the anode 51a and the peripheral electrode 75b under the control of the voltage setting unit 76 to set the voltage between the cathode 75 and the anode 51a. Such voltage application produces a small positive column PC between the anode 51a and the center electrode 75a, and can prevent occurrence of arc discharge at the initial stage of film deposition.

Such application of the voltage or current can allow a stable positive column PC to be formed at the upper portion of the center portion of the substrate 1. Then, the control unit 76a applies the voltage or current in such a way that the value of the voltage or current between the anode 51a and the center electrode 75a becomes less than the value of the voltage or current between the anode 51a and the peripheral electrode 75b to approximate the temperature between the anode 51a and the center electrode 75a to the temperature between the anode 51a and the peripheral electrode 75b or make those temperatures approximately identical before performing film deposition on the substrate 1.

In the embodiment, as described above, the cathode 75 comprises the center electrode 75a and the peripheral electrode 75b, and the value of the voltage or current between the anode 51a and the center electrode 75a and value of the voltage or current between the anode 51a and the peripheral electrode 75b can be independently set. At the rising of plasma, the voltage between the anode 51a and the center electrode 75a is set higher than the voltage between the anode 51a and the peripheral electrode 75b. Accordingly, the positive column PC can be formed with the distance between the anode 51a and the cathode 75 made shorter. The voltage to be applied to the anode 51a and the cathode 75 cab be low, thereby suppressing the frequent occurrence of arc discharge or sparking.

Further, the current flowing across the peripheral electrode 75b is made smaller than the current flowing across the center electrode 75a to produce a positive column PC concentrated on the center of the substrate 1, after which the power to be applied to the peripheral electrode 75b is increased to increase the current flowing across the peripheral electrode 75b. This makes it possible to prevent local arc discharge which occurs at the initial stage of film deposition after which the positive column PC can be grown to the necessary size.

The present invention is not limited to the above-described embodiments and can be modified in various other forms. The following are some possible modifications.

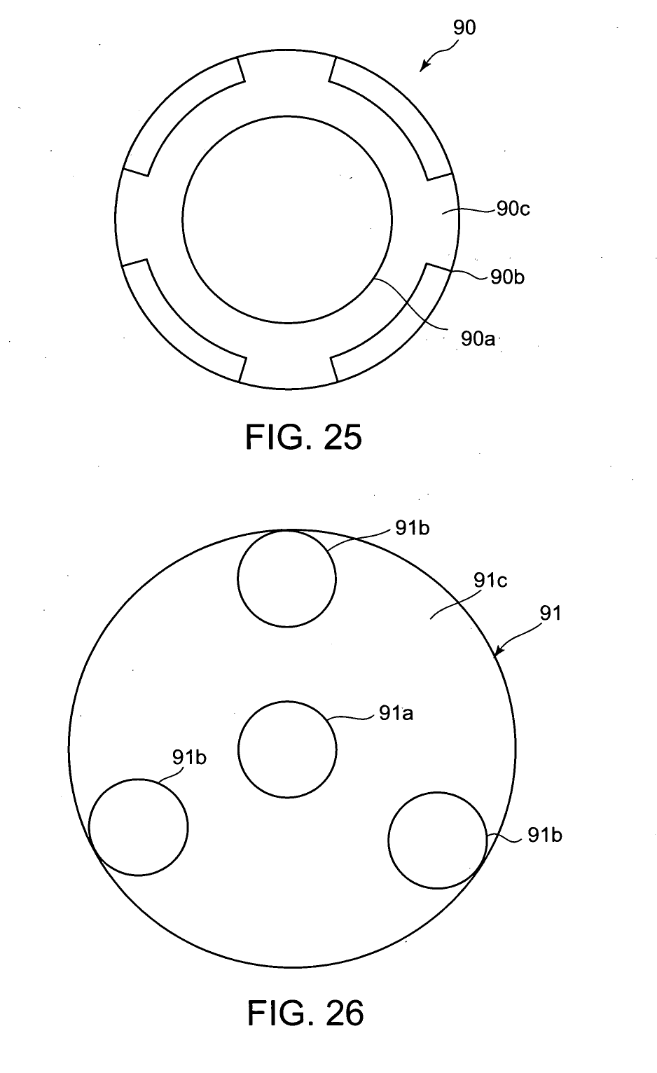

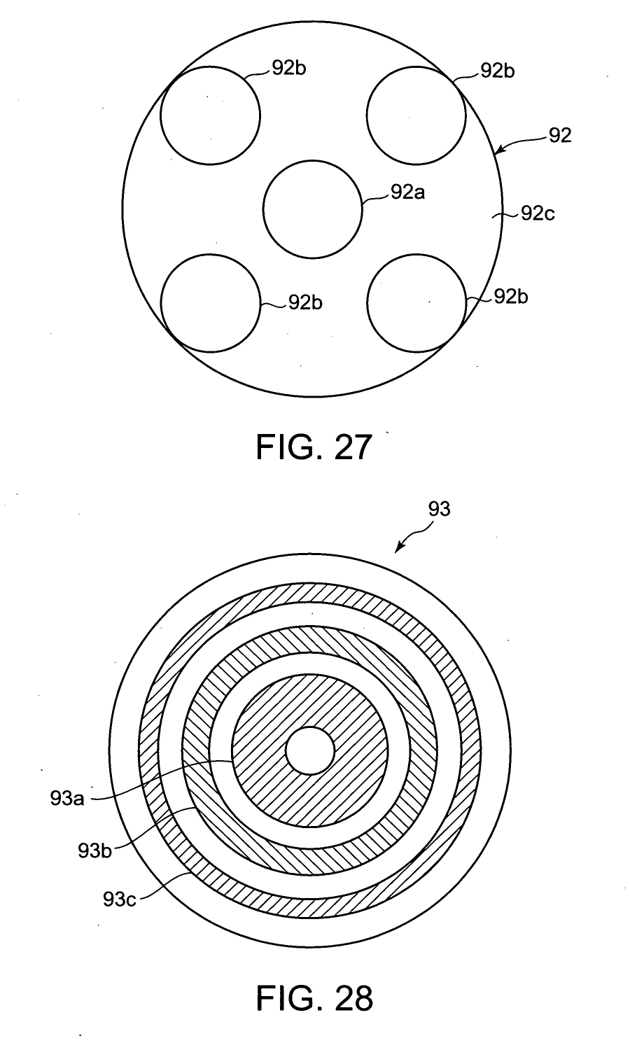

(a) The structure of the cathode 27, 35 comprising a plurality of electrodes can be adequately changed according to the sizes of the substrate 1 to be processed and the anode 11a. For example, a cathode 90 in FIG. 25 comprises a center electrode 90a and a plurality of peripheral electrodes 90b. In this case, a voltage or current the anode 11a and the cathode may be set individually for each of the peripheral electrodes 90b. An insulating part 90c of ceramics is filled between the center electrode 90a and the peripheral electrodes 90b. Each of cathodes 91, 92 as shown in FIGS. 26 and 27 has a plurality of circular peripheral electrodes 91b, 92b designed to have the same size as a center electrode 91a, 92a. In each cathode 91, 92, an insulating part 91c, 92c of ceramics is filled between the peripheral electrodes 91b, 92b and the center electrode 91a, 92a.

(b) Although the cathode 27, 35 is configured to have the center electrode 27a, 35a and the peripheral electrode 27b, 35b arranged concentrically, the cathode may be configured, like a cathode 93 shown in FIG. 28, to have three concentric center electrodes, namely a ring-shaped center electrode 93a, a first ring-shaped peripheral electrode 93b surrounding the center electrode 93a and apart therefrom, and a second ring-shaped peripheral electrode 93c surrounding the first ring-shaped peripheral electrode 93b and apart therefrom.

(c) The cooling member 12 can be modified too.

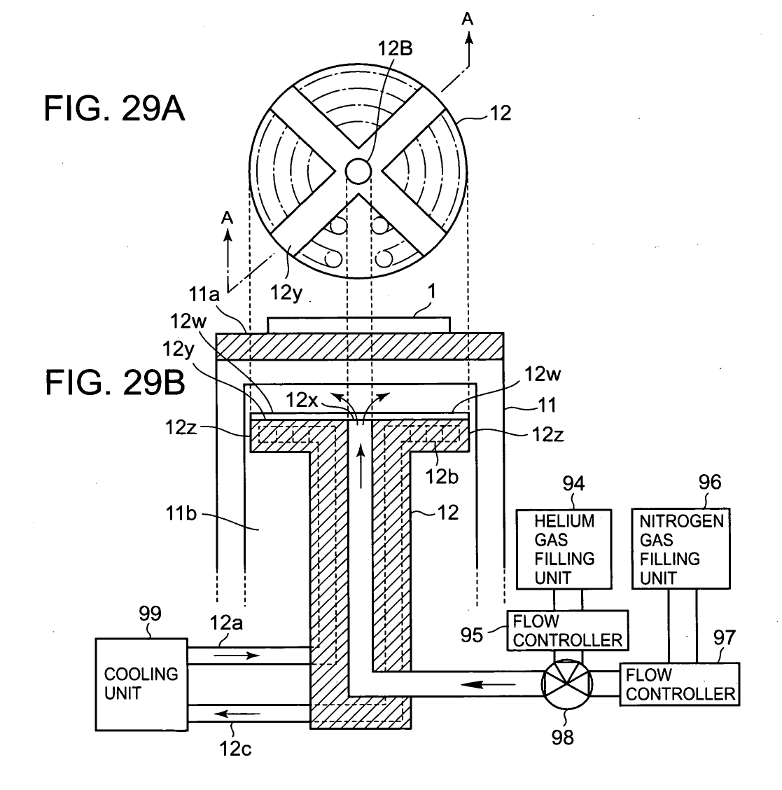

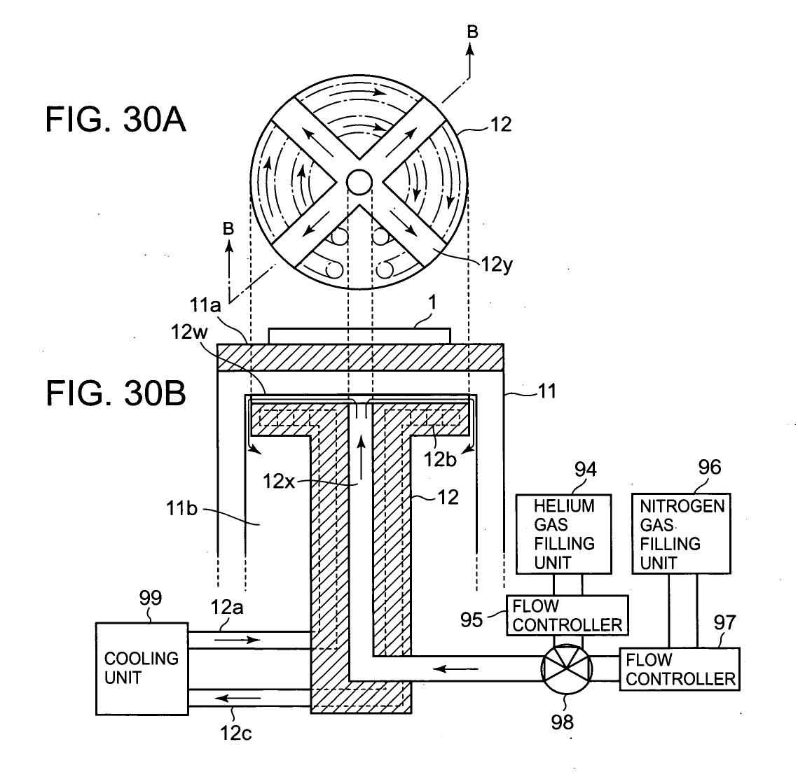

FIG. 29A is a top view showing another modification of the cooling member 12 of the DC plasma CVD apparatus, and FIG. 29B is a schematic cross-sectional view of the cooling member 12 along line A-A in FIG. 29A. FIG. 30A is a top view of the cooling member 12 in FIGS. 29A and 29B, and FIG. 30B is a schematic cross-sectional view illustrating the cooling operation of the cooling member 12 along line B-B in FIG. 30A. In the plasma CVD apparatus shown in FIGS. 29A and 29B, the cooling member 12 has conduits 12a, 12b and 12c through which a coolant supplied from a cooling unit 99 flows. On a top side 12w of the cooling member 12, a groove 12y extending from a vent 12x to a side face 12z of the cooling member 12 is formed. As shown in FIG. 30B, therefore, even when the top side 12w of the cooling member 12 abuts on the stage 11, the cooling gas passes and moves through a passage formed in the clearance between the groove 12y and the stage 11 as indicated by arrows to enable efficient ventilation and cooling. A helium gas whose discharge flow rate is adjusted by a flow controller 95 is sent to a three-way valve 98 from a helium gas filling unit 94. A nitrogen gas whose discharge flow rate is adjusted by a flow controller 97 is sent to the three-way valve 98 from a nitrogen gas filling unit 96. When the three-way valve 98 is open, cooled helium gas and cooled nitrogen gas are sprayed onto the abut surface of the stage 11 through the vent 12x to cool down the substrate 1.

### Ninth Embodiment

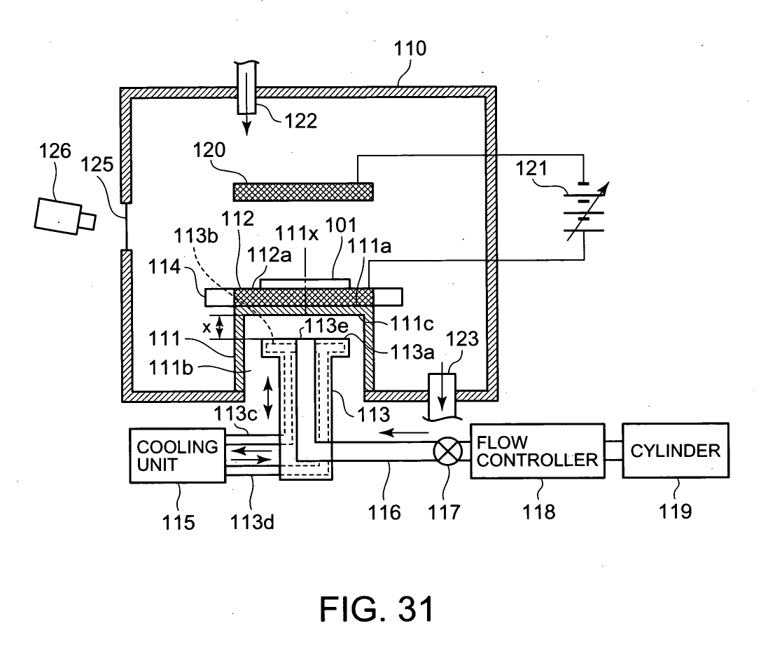

FIG. 31 shows a configurational example of a DC plasma CVD apparatus according to a ninth embodiment of the present invention.

The DC plasma CVD apparatus forms a film on the top surface of a substrate 101 to be processed, and has a chamber 110 as a reacting furnace. The chamber 110 shields the substrate 101 from the outside air.

A columnar steel stage 111 is disposed in the chamber 110, and a disc-shaped anode 112 is mounted on an electrode mounting surface 111a at the upper portion of the stage 111. The substrate 101, which is, for example, rectangular, is placed on an upper substrate mounting surface 112a of the anode 112. The anode 112 is formed of graphite and has a surface whose roughness mean value Ra is 5 μm or so.

The stage 111 underlying the anode 112 is provided with closed columnar space 111b and the electrode mounting surface 111a of the stage 111 is plate-like.

A columnar cooling member 113 is disposed in the space 111b of the stage 111. The cooling member 113 is provided to cool down the substrate 101 as needed, and is formed of a metal having a high thermal conductivity, such as copper. The cooling member 113 is configured to be movable up and down as indicated by arrows by a moving mechanism (not shown).

The upper end face of the cooling member 113 is an opposing face 113a facing a face 111c opposite to the electrode mounting surface 111a of the stage 111 (hereinafter called “bottom face”), and has a large outside diameter. As the cooling member 113 moves upward, the opposing face 113a faces the bottom face 111c of the stage 111 in such a way as to approach or abut on facing the bottom face 111c.

A flow passage 113b where a coolant, such as cooled water or calcium chloride solution, flows is formed in the cooling member 113. The flow passage 113b runs from a side face of the cooling member 113, passes near the opposing face 113a and reaches the side face of the cooling member 113 again. The flow passage 113b is connected to a cooling unit 113 via conduits 113c, 113d, so that the coolant is cooled by the cooling unit 115 and circulates between the flow passage 113b and the cooling unit 115.

A vent 113e is formed in the center of the opposing face 113a of the cooling member 113. The vent 113e penetrates a lower side face of the cooling member 113. At the lower side face of the cooling member 113, the vent 113e is connected to a conduit 116. The conduit 116 is connected to a cylinder 119 via a valve 117 and a flow controller 118. The cylinder 119 is filled with a helium gas, nitrogen gas or the like as a cooling gas. The cooling gas is filled in the space 111b, but is not filled on the substrate mounting surface 112a side of the anode 112.

Apparently, the cooling member 113 s provided with a mechanism for cooling the stage 111 with the coolant as well as a mechanism of cooling the stage 111 by spraying the cooling gas onto the stage 111 from the vent 113e. In cooling the anode 112 and substrate 101, therefore, a method of causing the opposing face 113a to partially or entirely abut on the bottom face 111c of the stage 111, a method of spraying the cooling gas onto the stage 111 with the opposing face 113a moved closer to the bottom face 111c, or both of the methods may be selected.

A cathode 120 is supported to face the substrate mounting surface 112a of the anode 112. A power source 121 which applies a voltage to generate plasma is connected between the cathode 120 and the anode 112.

Provided in the chamber 110 at a position higher than the cathode 120 is a gas supply pipe 122 for supplying a source gas, supplied from a source gas system (not shown), into the chamber 110. An gas exhaust pipe 123 for discharging the source gas is provided at the bottom portion of the chamber 110.

The gas supply pipe 122 and the gas exhaust pipe 123 respectively pass through holes provided in the chamber 110, and a sealant seals between each hole and the outer surface of each of the gas supply pipe 122 and the gas exhaust pipe 123 to secure the airtightness inside the chamber 110. Connected to the gas exhaust pipe 123 is an exhaust system (not shown) which discharges the source gas from the gas exhaust pipe 123 to adjust the atmospheric pressure in the chamber 110.

A window 125 is formed in the side face of the chamber 110 to permit observation of the interior of the chamber 110. In this case, a heat-resistant glass is fitted in the window 125 to secure the airtightness inside the chamber 110. A spectral radiance meter 126, which measures the temperature of the substrate 101 via the heat-resistant glass of the window 125, is disposed outside the chamber 110.

In carrying out film deposition on the substrate 101 using the DC plasma CVD apparatus, first, the substrate 101 is placed on the substrate mounting surface 112a of the anode 112. When the mounting of the substrate 101 is completed, next, the interior of the chamber 110 is depressurized using the exhaust system, followed by the supply of the source gas into the chamber 110 from the gas supply pipe 122. The source gas is a mixture of a reaction gas, such as methane, to be a material for film deposition, and a matrix gas (carrier gas), such as hydrogen, which does not become a material for film deposition by a predetermined ratio. In case of depositing a carbon film of graphite, diamond particles or the like on the carbon substrate 101, the reaction gas becomes a gas of a carbon-containing compound.

The pressure within the chamber 110 is set to a predetermined value or in such a way that a deviation from the predetermined value falls within an allowable range by adjusting the supply amount, and the discharge amount, of the source gas. The stage 111 is rotated at, for example, 10 rpm to turn the substrate 101 and the anode 112. Under the condition, a DV voltage is applied between the anode 112 and the cathode 120 to generate plasma. When plasma is generated, the plasma produces active species from the reaction gas, thereby starting film deposition on the substrate 101. Turning the substrate 101 and the anode 112 reduces a temperature variation depending on the position of the substrate 101, thereby preventing a variation in film deposition on the substrate 101.

To secure a desired film thickness by suppressing a deposition-oriented rise in the temperature of the substrate 101, or to change the film quality by changing the temperature of the substrate 101 during film deposition, the cooling mechanism provided at the cooling member 113 is selected and used adequately. That is, the opposing face 113a may be made to abut on the bottom face 111c while letting the coolant cooled by the cooling unit 115 flow in the flow passage 113b of the cooling member 113, or the cooling gas may be sprayed onto the bottom face 111c with the opposing face 113a allowed to approach the bottom face 111c, or the cooling gas may be sprayed onto the bottom face 111c with a part of the opposing face 113a allowed to abut on the bottom face 111c.

Because the surface temperature of the substrate 101 can be measured by the spectral radiance meter 126, the cooling timing for the substrate 101 and the voltage to be applied between the anode 112 and the cathode 120 can be controlled according to a change in the surface temperature of the substrate 101 caused by the plasma.

When a predetermined time passes since the initiation of film deposition so that the film deposition comes to an end stage, application of the voltage between the anode 112 and the cathode 120 is stopped, then the supply of the source gas is stopped and a nitrogen gas is supplied into the chamber 110 as a purge gas to set the pressure therein to normal pressure, after which the substrate 101 is removed.

The advantages of the DC plasma CVD apparatus will be described next.

As film deposition on the substrate 101 is carried out, the substrate 101, the anode 112 and the cathode 120 are exposed to the plasma generated between the anode 112 and the cathode 120 to be heated. While a part of the energy given to the substrate 101 is transmitted to the chamber 110 by heat radiation, the energy is mostly transmitted to the anode 112 and the stage 111 from the substrate 101 and further transmitted to the cooling member 113 via the stage 111. As the amount of transfer heat is balanced out with the amount of heat diffused, the temperature of the substrate 101 is kept constant.

Film deposition was performed both in a case where the anode 112 is formed of graphite (hereinafter this electrode is called “graphite electrode”) and in a case where the anode 112 is formed of molybdenum (hereinafter this electrode is called “molybdenum electrode”), and the results were compared.

In either case of the graphite electrode and the molybdenum electrode, the deposition conditions were such that the source gas with the flow rate of methane in the reaction gas set to 50 sccm and the flow rate of hydrogen in the matrix gas set to 500 sccm was supplied into the chamber 110 and the general pressure was kept at 7999.32 Pa by adjusting the discharge speed. In addition, plasma was generated by applying power in such a way that the densities of the currents between the cathode 120 and the graphite electrode and the molybdenum electrode became 0.15 A/cm² (current/electrode area).

The roughness mean value Ra of the surface of the molybdenum electrode was 1.5 μm, the thermal conductivity λ by bulk movement was 132 W·m⁻¹·K⁻¹. The roughness mean value Ra of the surface of graphite to be the anode 112 was 5 μm, the thermal conductivity λ by bulk movement was 120 W·m⁻¹·K⁻¹.

Silicon with a thickness of 0.5 mm was used for the substrate 101, and a distance x between the opposing face 113a and the bottom face 111c of the stage 111 in FIG. 31 was set to 60 mm for about two hours since the start time of the film deposition in order to change the temperature of the substrate 101. During this period, a carbon nanowall was structured on the substrate 101 in the plasma CVD apparatus using the graphite electrode as a plurality of petaloid (fan-shaped) thin carbon pieces having curved surfaces stood upright and linked together in random directions. Each thin carbon piece was formed by several to several tens of graphene sheets each having a lattice pitch of 0.34 nm. Thereafter, the distance x was approximated to 0.5 mm. Then, a helium gas as the cooling gas was supplied into the lower space 111b of the stage 111 via the vent 113e at 500 sccm, lowering the temperature of the substrate 101. During this period, in the plasma CVD apparatus using the graphite electrode a microcrystal diamond film containing microcrystal diamond particles with a grain size of nanometer order (less than 1 μm) was deposited on the carbon nanowall on the substrate 101, a part of the carbon nanowall mainly grew with the growth of the microcrystal diamond particles, and penetrated the clearance in the microcrystal diamond film, thereby forming a needle-like carbon rod protruding from the surface of the microcrystal diamond film. This carbon rod has carbon formed inside, and, unlike a cylindrical structure, such as a carbon nanotube which is a thin carbon layer with a hollow interior, is rigid and has a high mechanical strength because it is grown from a carbon nanowall.

The spectral radiance meter 126 was used to measure the temperature of the substrate 101 and perform the spectrometry of the intensity of the infrared radiation from the substrate 101, and the temperature of the substrate 101 and the emissivity thereof were evaluated by using gray body approximation.

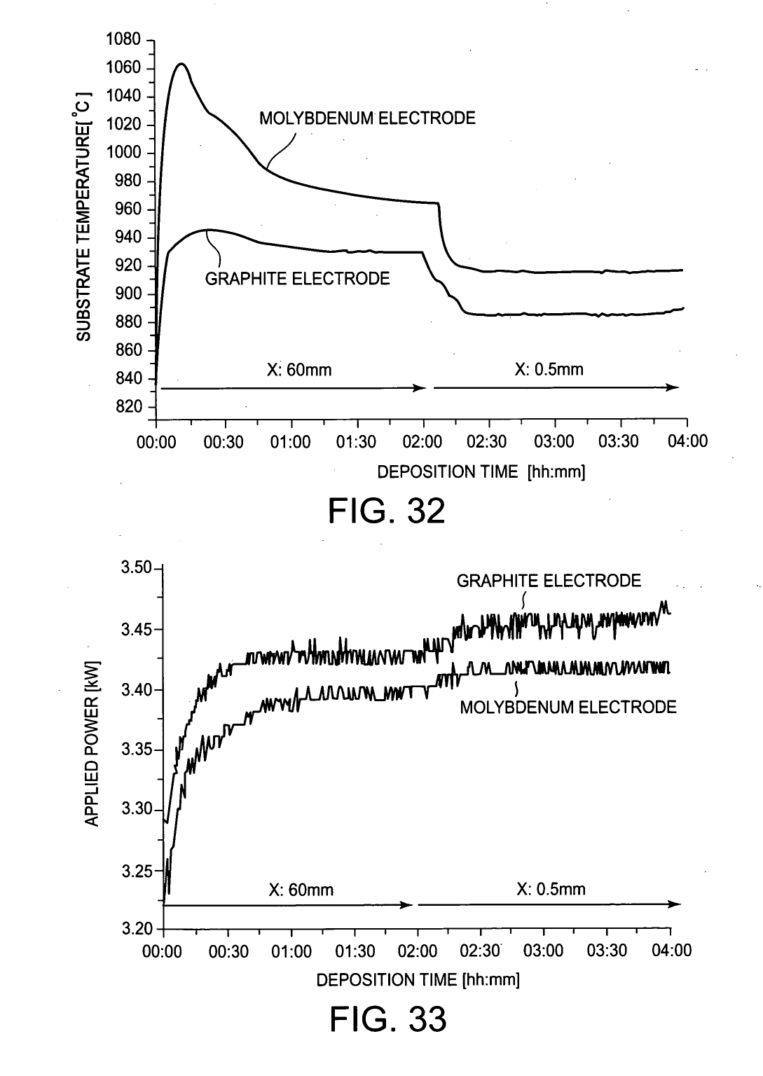

FIG. 32 is a graph showing the temperatures of the substrate 101 measured for different anodes 112.

As shown in FIG. 32, for either electrode, the temperature of the substrate 101 reaches the peak point within 30 minutes after initiation of film deposition, after which the temperature of the substrate 101 tends to fall with the current density being constant. The reason why the temperature of the substrate 101 has a falling tendency is that as a carbon nanowall which is a bulk of graphen sheets is deposited on the substrate 101, the emissivity of the upper surface of the substrate 101 rises, thus increasing the amount of transfer heat by the radiation in the chamber from the top surface of the substrate 101. Further, after the emissivity of the substrate 101 reaches a constant value as a result of the deposition of the carbon nanowall on the substrate 101, the temperature of the substrate 101 is stable. Such a phenomenon shows that at the time of CVD deposition at the temperature of the substrate 101 of above 900° C., the ambient emissivity greatly affects the temperature of the substrate 101.

The comparison of the temperatures of the substrate 101 varying for different electrodes showed that in the initial deposition area where the temperature of the substrate 101 would greatly vary, the temperature of the substrate 101 on the graphite electrode was lower by 100° C. or more than the temperature of the substrate 101 on the molybdenum electrode. In the subsequent state where the temperature becomes stable, even with the distance x being 0.5 mm, the temperature of the substrate 101 in the case of the graphite electrode becomes lower by 40° C. than the temperature of the substrate 101 in the case of the molybdenum electrode.

FIG. 33 is a graph showing a change in power applied to plasma with the applied current being constant in the furnance in FIG. 32.

At the time of the film deposition, the density of the current flowing between the anode 112 and the cathode 120 is controlled to be constant at 0.15 A/cm², while the applied voltage automatically varies according to the gas state. Actually, the lower the density of the gas between electrodes is, the lower the applied voltage tends to be. In the case of the molybdenum electrode which makes the temperature of the substrate 101 higher, the ambient gas temperature is increased by the substrate 101 and the electrode, and the density is reduced accordingly, so that the voltage for allowing the current with the same density to flow becomes lower for the graphite electrode which makes the temperature of the substrate 101 lower. While the power applied in the case of the molybdenum electrode always becomes lower than that in the case of the graphite electrode, therefore, the amount of a change in power is equal to or less than 1.5% of the applied power.

The reason why there is always a difference of 100° C. in the temperature of the substrate 101 between the molybdenum electrode and the graphite electrode even though the applied power hardly changes is that the graphite electrode is easier to let heat escape than the molybdenum electrode in the temperature area. It seems that the graphite electrode with a lower thermal conductivity and a rougher surface than the molybdenum electrode tends to easily escape heat because the thermal radiation gives greater contribution on the thermal conductivity than the contact-oriented contribution on the thermal conductivity. Because of the large contact heat resistance, if the thermal conductivity of the electrode material itself is not significant, molybdenum has an emissivity of 0.3 or so due to surface reflection as compared with graphite having an emissivity of 0.9 or greater, so that it can be easily explained that the graphite electrode makes the temperature of the substrate 101 lower.

The tendency that the temperature difference between the molybdenum electrode and the graphite electrode becomes greater as the temperature of the substrate 101 becomes higher corresponds to the fact that the amount of transfer heat for the contact-oriented thermal conductivity changes in proportional to a temperature difference, whereas the amount of transfer heat for the heat-radiant-oriented thermal conductivity changes in proportional to the fourth power of the absolute temperature, so that the higher the temperature of the substrate 101 is, the greater the amount of transfer heat discharged rapidly becomes, making it difficult to increase the temperature. Those also imply that the rate of heat radiation is greater in the heat conductance in film deposition.

To estimate the amount of transfer heat by a heat transfer system, let us consider a case where a mirror-polished substrate is placed on an anode with the roughness mean value Ra. Given that a surface y is the bottom side of the substrate, a surface z is the top surface of the anode, and the bottom side y of the substrate is a mirror surface, the surface can be made to be substantially a plane as compared with the roughness mean value Ra of the anode. Therefore, the contact-oriented heat transfer can be considered to be made through the projection of the anode with a length Ra. In this case, given that the temperature of the substrate 101 is T₁ and the temperature of the anode is T₂, the amount of transfer heat Wₜ₁ per unit area which flows from the substrate to the anode due to the contact can be expressed as follows.

$${W}_{t 1} = r \times ( \frac{λ}{Ra} ) ( {T}_{1} - {T}_{2} ) \qquad Eq . 1$$

where λ is the thermal conductivity of the anode material, r is a ratio of the apparent contact area between the substrate 101 and the anode 112 and the true contact area between the substrate 101 and the anode 112, and Ra is the roughness mean value of the surface. Although a correction term is introduced for the interval between the substrate 101 and the anode 112 in a more accurate equation, such is omitted for the rough calculation is intended here.

In addition to the heat transfer by the contact between solids, there is a heat conductance transmitted via a gas in the clearance between the substrate 101 and the anode 112. If the heat transfer is simplified as heat transfer through a still layer located between two parallel plates with different temperatures, in the environment of the pressure of 0.1 or less which is normal for plasma CVD at the time of acquiring the data shown in FIG. 32, the mean free path can be considered sufficiently larger than the surface roughness of the bottom side of the substrate. Therefore, transfer heat can be considered as free molecule heat conductance. At this time, the amount of transfer heat W_{g1} can be expressed as follows.

$${W}_{{g}_{1}} = ( 1 - r ) \times α \cdot Λ \cdot p \cdot ( {T}_{1} - {T}_{2} ) \\ Λ = \frac{1}{2} ( \frac{γ + 1}{γ - 1} ) \sqrt{\frac{k}{2 π mT}} \\ T = \frac{{T}_{1} + {T}_{2}}{2} \qquad Eq . 2$$

where Λ is a free molecule heat conductivity, α is an adaptive coefficient, p is pressure, γ is a specific heat ratio, k is a Bolzmann constant, and m is the mass of the gas molecule. For simplification of rough calculation, the calculation is performed with the adaptive coefficient set to the maximum value of 1, and the specific heat ratio and the mass of the gas molecule being 7/5.3.3×10⁻²⁷ Kg which are the values for the hydrogen molecule that is the principle gas of the plasma.

Finally, let us consider the amount of radiation-oriented transfer heat. With the anode taken as an infinite parallel plate, the amount of transfer heat Wᵣ₁ to be transferred to the plane z from the plane y by the heat radiation can be expressed as follows.

$${W}_{r 1} = ( 1 - r ) \times σ ( {T}_{1}^{4} - {T}_{2}^{4} ) \cdot \frac{1}{\frac{1}{{ɛ}_{1}} + \frac{1}{{ɛ}_{2}} - 1} . \qquad Eq . 3$$

where ε₁ and ε₂ are respectively the emissivities of the plane y and the plane z, σ is a Stefan-Bolzmann constant (5.67×10⁻⁸ Wm⁻²K⁻⁴).

For those three transfer heat mechanisms, calculation of the amount of transfer heat is calculated in cases where the emissivity of silicon to be the substrate is 0.6, the emissivity of molybdenum is 0.3, the emissivity of graphite is 0.9, the ratio of the apparent contact area between the substrate 101 and the anode 112 and the true contact area between the substrate 101 and the anode 112 is 1/1000000, the substrate temperature is 920° C., the anode substrate is 860° C., and the substrate area is 30 mm. For the molybdenum electrode, the contact thermal conductance to the substrate 101 becomes about 5 W, the free-molecule oriented thermal conductance between the molybdenum electrode and the substrate 101 becomes about 10 W, and the thermal-radiant heat becomes about 5 W, whereas for the graphite electrode, the contact thermal conductance to the substrate 101 becomes about 1 W, the free-molecule oriented thermal conductance between the graphite electrode and the substrate 101 becomes about 10 W, and the thermal-radiant heat becomes about 11 W. When the stress is not applied to the interface and r becomes a very small value, heat radiation which does not depend on r and the ratio of transfer heat by the free-molecule thermal conductance become higher.

Let us consider a case where heat transfer to the substrate from plasma is constant with small r. Even if the ratio r of the apparent contact area between the substrate and the anode and the true contact area between the substrate and the anode varies due to the layout deviation, the absolute value of r is small so that a change in the amount of transfer heat to the anode from the substrate hardly depends on the radiation-oriented transfer heat and changes only the amount of contact-oriented transfer heat which changes in proportional to r. At this time, as the contribution of the radiation-oriented transfer heat becomes greater, most of the change in the contact-oriented transfer heat changes in proportional to (T₁⁴ T₂⁴), and can be compensated by a change in radiation-oriented transfer heat which is large with respect to a change in temperature, thus making it possible to relatively reduce the amount of a change in T₁. The graphite electrode which shows large contribution to the radiation-oriented transfer heat can suppress a variation in substrate temperature with respect to a change in for an electrode having a small emissivity, thus stabilizing the film deposition conditions.

The use of the graphite electrode for the anode 112 can prevent an unnecessary deposit from being deposited on the anode 112, as will be described below.

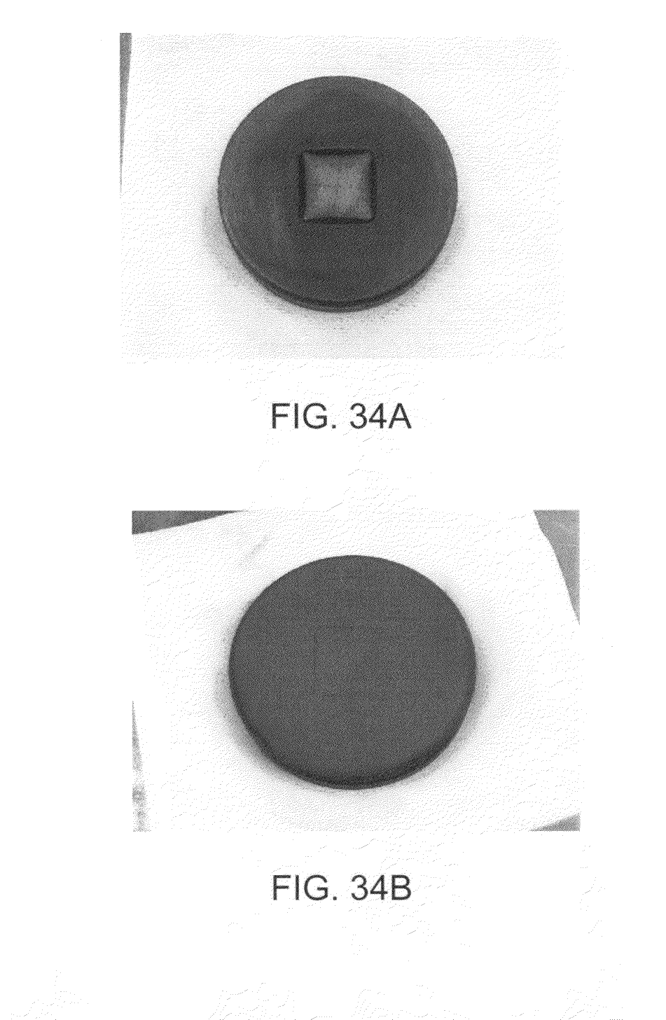

FIGS. 34A and 34B are photographs respectively showing the states of the molybdenum electrode and the graphite electrode after film deposition.

With the anode 112 being the molybdenum electrode, as shown in FIG. 34A, a carbon film was formed on the portion where the substrate 101 was not mounted after film deposition. Therefore, when a new substrate was placed on the molybdenum electrode having the carbon film formed, the surface roughness at the portion where the carbon film was formed further varied, so that the contact-oriented transfer heat made temperature control further difficult.

For the graphite electrode, there hardly existed a deposit as shown in FIG. 34B, so that more stable temperature control with no variation in surface roughness became possible.

Although the resistance between the carbon film of the molybdenum electrode and the bottom side of the molybdenum electrode was 3 MΩ or greater, and a variation in the applied voltage between the anode and the cathode itself occurred, the resistance between the top surface of the graphite electrode (regardless of the portion where the substrate was placed or the portion where the substrate was not place) and the bottom did not change from that before film deposition, and the applied voltage between the top surface of the anode and the cathode could be made uniform within the plane.

Because with the use of the graphite electrode for the anode 112, a carbon film which becomes an insulator is hardly deposited on the anode 112, so that the substantial shape of the anode 112 does not change during film deposition. This can prevent a change in the shape of plasma, from which stabilization of film deposition can be expected.

The present invention is not limited to the above-described embodiments, and can be modified in various other forms.

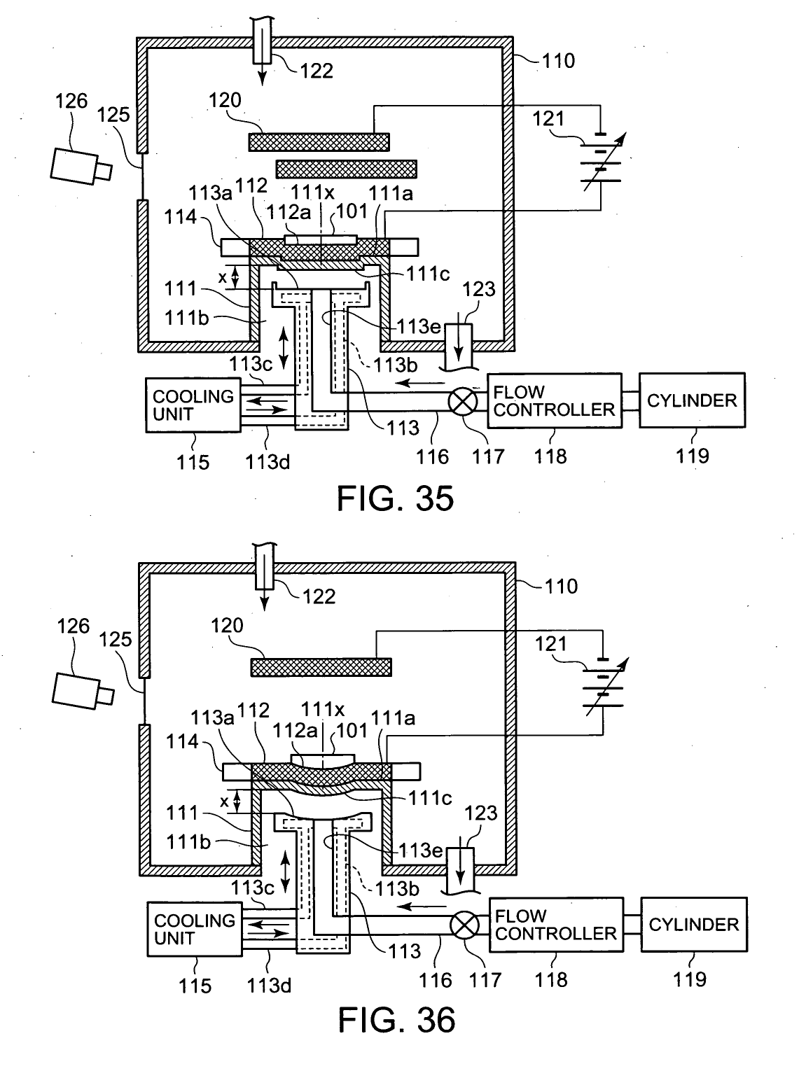

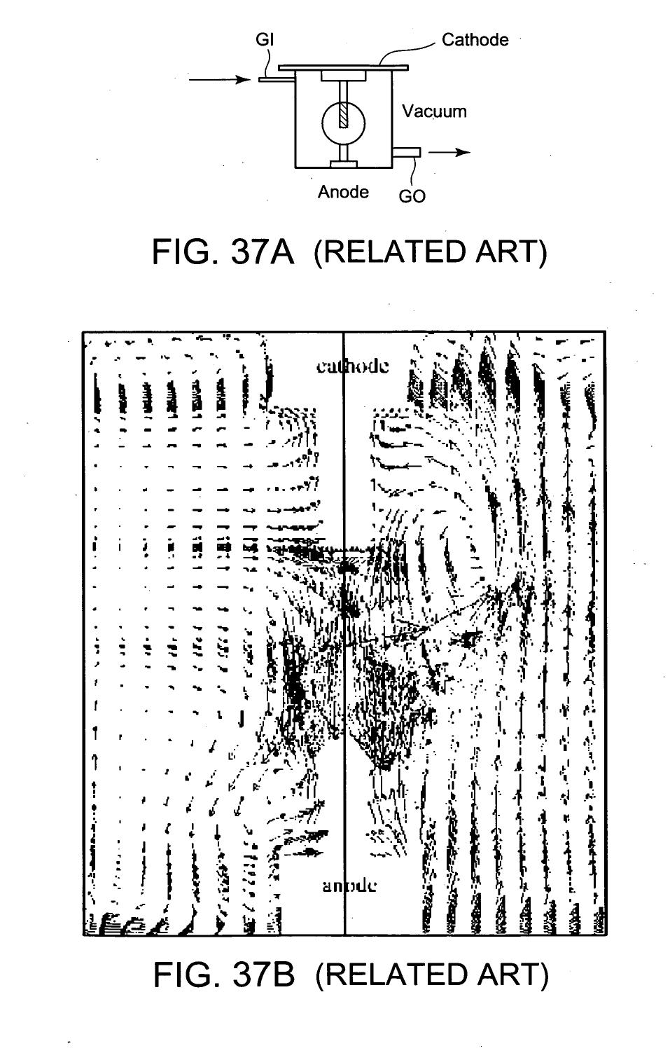

As shown in FIG. 35, a recess where the substrate 101 can be received may be formed in the substrate mounting surface 112a to widen the thermal radiant surface of the anode 112 to increase the thermal radiation.

In this case, it is preferable that the bottom side of the anode 112 be a projection protruding to match with the depth of the recess of the anode 112 to set the uniform of the anode 112 even to make the temperature of the anode 112 uniform, and it is preferable that a recess be formed in the electrode mounting surface 111a of the stage 111 to match with the projection of the anode 112 and the bottom side of the stage 111 be a projection protruding to match with the depth of the recess of the electrode mounting surface 111a to set the uniform of the stage 111 even to make the temperature of the stage 111 uniform. It is then preferable that a recess be formed in the opposing face 113a to be fitted in the bottom side of the stage 111.

As shown in FIG. 36, even if the bottom side of the substrate 101 is not smooth, a recess may be formed t match with the shape of the substrate 101 so that the substrate 101 can be fitted in the recess.

In this case, it is preferable that the bottom side of the anode 112 be a projection protruding to match with the depth of the recess of the anode 112 to set the uniform of the anode 112 even to make the temperature of the anode 112 uniform, and it is preferable that a recess be formed in the electrode mounting surface 111a of the stage 111 to match with the projection of the anode 112 and the bottom side of the stage 111 be a projection protruding to match with the depth of the recess of the electrode mounting surface 111a to set the uniform of the stage 111 even to make the temperature of the stage 111 uniform. It is then preferable that a recess be formed in the opposing face 113a to be fitted in the bottom side of the stage 111.

The structure where the power source 121 applies a DV voltage between the anode 112 and the cathode 120 is not restrictive, and a plasma CVD apparatus which applies a high frequency may be used instead. In this case, the use of graphite for the electrode which cools the substrate 101 can cool the substrate with the heat radiation, and can stabilize film deposition.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2007-062065 filed on Mar. 12, 2007, Japanese Patent Application No. 2007-073357 filed on Mar. 20, 2007 and Japanese Patent Application No. 2007-325296 filed on Dec. 17, 2007 including specification, claims, drawings and summary. The disclosure of the above Japanese Patent Applications is incorporated herein by reference in its entirety.

What is claimed is:

1. A plasma CVD apparatus comprising:
a reacting furnace
a first electrode which is disposed in the reacting furnace and on which a substrate is mounted;
a second electrode that is disposed above and opposite the first electrode and generates plasma with the first electrode; and
a first gas supply nozzle that is disposed at a height between a height of the first electrode and a height of the second electrode, and has a plurality of ejection ports formed and arranged in such a way as to surround an area between the first electrode and the second electrode where plasma is generated.

2. The plasma CVD apparatus according to claim 1, wherein a source gas which forms active species with the plasma is introduced by the first gas supply nozzle.

3. The plasma CVD apparatus according to claim 1, wherein a source gas and a matrix gas which form active species with the plasma are introduced by the first gas supply nozzle.

4. The plasma CVD apparatus according to claim 1, wherein the first gas supply nozzle laterally ejects a gas toward a center axis of the first electrode from the plurality of ejection ports.

5. The plasma CVD apparatus according to claim 1, wherein the first gas supply nozzle is disposed in such a way as to surround the first electrode.

6. The plasma CVD apparatus according to claim 1, wherein the plurality of ejection ports of the first gas supply nozzle are arranged at equal intervals.

7. The plasma CVD apparatus according to claim 1, wherein the plurality of ejection ports of the first gas supply nozzle have equal distances to a center axis of the first electrode.

8. The plasma CVD apparatus according to claim 1, wherein ejection ports of each ejection port set having two of the plurality of ejection ports of the first gas supply nozzle are so arranged as to face each other with a center axis of the first electrode being a center.

9. The plasma CVD apparatus according to claim 1, wherein a height of the plurality of ejection ports of the first gas supply nozzle is set higher than a topmost point of an area where a positive column of the plasma is generated.

10. The plasma CVD apparatus according to claim 1, wherein the first gas supply nozzle has a ring shape.

11. The plasma CVD apparatus according to claim 1, wherein the first gas supply nozzle is pipes facing each other along a side of the second electrode.

12. The plasma CVD apparatus according to claim 1, further comprising a second gas supply nozzle that ejects a matrix gas from above the second electrode toward a gas ejected from the first gas supply nozzle.

13. The plasma CVD apparatus according to claim 1, further comprising a plurality of discharge conduits disposed under the first electrode to discharge a gas from the reacting furnace.

14. The plasma CVD apparatus according to claim 1, further comprising a plurality of discharge conduits that are disposed under the first electrode so as to surround the first electrode, and discharge a gas from the reacting furnace.

15. The plasma CVD apparatus according to claim 1, wherein the second electrode comprises a plurality of electrodes, and
voltages or currents between the electrodes of the second electrode and the first electrode are individually set to arbitrary values.

16. The plasma CVD apparatus according to claim 15, wherein the plurality of electrodes include a center electrode facing a center portion of the first electrode and a peripheral electrode facing a peripheral portion of the first electrode, and
the value of the voltage or current between the center electrode and the first electrode is set higher than the value of the voltage or current between the peripheral electrode and the first electrode at a time of rising.

17. The plasma CVD apparatus according to claim 15, wherein the plurality of electrodes include a center electrode facing a center portion of the first electrode and a peripheral electrode facing a peripheral portion of the first electrode, and
after a positive column is formed between the center electrode and the first electrode, the value of the voltage or current between the center electrode and the first electrode is set less than the value of the voltage or current between the peripheral electrode and the first electrode.

18. The plasma CVD apparatus according to claim 15, wherein an insulator is disposed between the plurality of electrodes.

19. The plasma CVD apparatus according to claim 1, wherein the first electrode has a surface formed of a graphite.

20. A plasma CVD apparatus comprising:
an electrode which has a surface formed of a graphite and on which a substrate to be processed is mounted; and
a plasma generating unit that generates plasma on the electrode to perform a predetermined process on the substrate.

21. The plasma CVD apparatus according to claim 20, further comprising a stage that supports the electrode; and
a cooling unit that cools down the stage to cool the electrode, thereby lowering a temperature of the substrate.

22. The plasma CVD apparatus according to claim 21, wherein the cooling unit starts cooling the substrate when film deposition on the substrate is carried out.

23. The plasma CVD apparatus according to claim 20, wherein the predetermined process which is performed by the plasma generating unit is film deposition on the substrate by plasmanization using hydrocarbon as a reaction gas.

24. A film deposition method comprising:
applying a voltage between a first electrode on which a substrate is mounted and a second electrode; and
ejecting a reaction gas from a plurality of ejection ports arranged in such a way as to surround an area where plasma is generated.
